(19) United States
(12) Patent Application Publication
(10) Pub. No.: US 2023/0360894 A1
(43) Pub. Date: Nov. 9, 2023

(54) HIGH-CONDUCTANCE VACUUM VALVES FOR WAFER PROCESSING SYSTEMS

(71) Applicant: Lam Research Corporation, Fremont, CA (US)

(72) Inventors: Gabriel Pioux, Davis, CA (US); Allan Ronne, Santa Clara, CA (US)

(21) Appl. No.: 18/006,531

(22) PCT Filed: Jul. 23, 2021
(86) PCT No.: PCT/US2021/042951

§ 371 Date: Jan. 23, 2023

Related U.S. Application Data
(60) Provisional application No. 62/706,004, filed on Jul. 24, 2020.

(51) Int. Cl. H01J 37/32

(52) U.S. Cl. CPC H01J 37/32834; H01J 37/32715; H01J 37/32183

(57) ABSTRACT

A semiconductor processing chamber performs various wafer processing operations that involve at least one of pumping the chamber to high vacuum states and regulating a vacuum (e.g., during introduction of process gases, as gas infiltrates the chamber, as reactions emit gases, as a wafer off-gases, etc.). A vacuum valve may be fluidically coupled between a vacuum pumping system and at least a portion of the semiconductor processing chamber. The vacuum valve may be a high-conductance multi-stage poppet valve enabling a relatively high gas flow rate and/or low pressure drop. In an open state, the multi-stage design of the poppet valve may have larger cross-sectional openings, in aggregate, than a comparable single-stage poppet valve could achieve, thereby increasing conductance.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Vacuum pumps are widely used in semiconductor processing equipment to provide a clean and/or low-pressure environment in a processing chamber. Such vacuum pumps may be fluidically connected to the processing chamber via a valve such as a poppet-style valve and used to remove byproducts, unused etch reactants, unused deposition precursors, and/or other gases and materials from the processing chamber.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

In one aspect an apparatus may be provided that includes a multi-stage poppet valve, where the multi-stage poppet valve may include a valve seat a valve seat including a gas-permeable region, two or more movable bodies including (i) a movable center body including a gas-impermeable region and (ii) at least one movable intermediary body, each movable intermediary body including a gas-impermeable region and a gas-permeable region, the gas-impermeable region of each movable intermediary body surrounding the gas-permeable region of that movable intermediary body, where each of the movable bodies may be translatable relative to the valve seat along a first axis and the movable bodies may be transitionable between at least a first configuration and a second configuration. The movable bodies, in the first configuration, may be positioned proximate the valve seat to provide a first amount of flow restriction. The movable bodies, in the second configuration, may be positioned at spaced-apart locations along the first axis and relative to each other and the valve seat to provide a second amount of flow restriction less than the first amount of flow restriction and such that a first gap may be visible along the first axis, the first gap being between at least two of the movable bodies in a first set of the movable bodies and such that corresponding second gaps may be visible along the first axis, the second gaps being between each of the movable bodies in the first set of the movable bodies and the valve seat.

In another aspect of the apparatus, the movable bodies may be additionally transitionable between a continuum of additional configurations between the first and second configurations. As the movable bodies transition from the first configuration, through the continuum of additional configurations, and into the second configuration, the movable bodies may provide a variable amount of flow restriction that ramps down from the first amount of flow restriction to the second amount of flow restriction.

In another aspect, the apparatus may further include at least one actuator configured to translate the movable bodies, where each of the movable bodies may include a main body and each movable body of the movable bodies may include at least one wing that extends off the main body and mechanically couples to a respective portion of the actuator.

In another aspect, the apparatus further may include at least one actuator configured to translate the movable bodies. At least one of the movable bodies may include a main body, at least one movable body of the movable bodies may include at least one wing that extends off the main body and mechanically couples to a portion of the actuator, and at least one movable body of the movable bodies may include at least one bracket that extends off the main body and mechanically engages another one of the movable bodies for a partial fraction of the translation of the movable bodies between the first and second configurations.

In another aspect, the apparatus may include a semiconductor processing chamber having walls defining an interior volume, a process gas delivery system configured to introduce one or more process gases into the interior volume of the semiconductor processing chamber, and a vacuum foreline in fluidic communication with the interior volume of the semiconductor processing chamber. The multi-stage poppet valve may be fluidically interposed between the vacuum foreline and the process gas delivery system.

In another aspect, the apparatus may include at least one actuator configured to translate the movable bodies, a substrate support, and a substrate support arm configured to hold the substrate support within the semiconductor processing chamber. The substrate support arm may mechanically couple a wall of the semiconductor processing chamber to the substrate support, each of the movable bodies may include a main body and at least one wing that extends off the main body, the wing of each movable body may mechanically couple that movable body to a portion of the actuator, and the substrate support arm and at least one wing of each movable body may be aligned along a second axis parallel to the first axis.

In another aspect,of the apparatus, when the multi-stage poppet valve is in the second configuration, there may be an average gap of X between adjacent portions of the movable intermediary body and the walls of the semiconductor processing chamber and there may be an average gap of Y between adjacent portions of the movable center body and the walls of the semiconductor processing chamber. The movable intermediary body may be configured to translate along the first axis a distance of at least 75% of X when transitioning from the first configuration to the second configuration. Similarly, the movable center body may be configured to translate along the first axis a distance of at least 75% of Y when transitioning from the first configuration to the second configuration.

In another aspect of the apparatus, the distance the movable intermediary body is configured to translate along the first axis, when transitioning from the first configuration to the second configuration, may be no more than 125% of X. Similarly, the distance the movable center body is configured to translate along the first axis, when transitioning from the first configuration to the second configuration, may be no more than 125% of Y.

In another aspect of the apparatus, the multi-stage poppet valve may include a first actuator or set of actuators configured to translate the movable center body, at least partially independent of the movable intermediary body, along the first axis and between the first and second configurations, and a second actuator or set of actuators configured to translate the movable intermediary body, at least partially independent of the movable center body, along the first axis and between the first and second configurations.

In another aspect of the apparatus, the movable bodies may be further transitionable to a third configuration in which the movable center body is positioned at a spaced-apart location along the first axis relative to the valve seat and in which the movable intermediary body may be positioned proximate the valve seat to provide a third amount of flow restriction that may be between the first and second amounts of flow restriction. The multi-stage poppet valve may further include at least one actuator and at least one shaft that is translated along the first axis by operation of the at least one actuator. The shaft may have (i) a first portion that engages with the movable center body and (ii) a second portion that engages with the movable intermediary body.

In another aspect of the apparatus, the movable bodies may be further transitionable to a third configuration in which the movable center body is positioned at a spaced-apart location along the first axis relative to the valve seat and the movable intermediary body is positioned proximate the valve seat to provide a third amount of flow restriction that is between the first and second amounts of flow restriction. The multi-stage poppet valve may further include at least one actuator and at least one stepped shaft that couples the at least one actuator to both the movable center body and the movable intermediary body. A first portion of the stepped shaft may have a first diameter and a second portion of the stepped shaft may have a second diameter larger than the first diameter. The first portion of the stepped shaft may be coupled to the movable center body and may pass between portions of the movable intermediary body. The second portion of the stepped shaft may be configured to press against the portions of the movable intermediary body in order to translate the movable intermediary body along the first axis.

In another aspect of the apparatus, the multi-stage poppet valve may further include at least first and second seals. The first seal may contact both the valve seat and the movable intermediary body at least when in the first configuration. The second seal may contact both the movable intermediary body and the movable center body at least when in the first configuration.

In another aspect of the apparatus, in the first configuration, the movable intermediary body may nest within the gas-permeable region of the valve seat and the movable center body may nest within the gas-permeable region of the movable intermediary body such that the valve seat, movable intermediary body, and movable center body may all overlap each other when viewed along an axis perpendicular to the first axis.

In another aspect of the apparatus, in the first configuration, the movable bodies and the valve seat may be disposed in a stacked arrangement.

In another aspect of the apparatus, the second configuration may provide a minimum flow restriction condition of the multi-stage poppet valve.

In another aspect of the apparatus, the valve seat and two or more movable bodies may be configured such that, in the first configuration, the multi-stage poppet valve is, in aggregate, gas-impermeable.

In another aspect of the apparatus, the gas-impermeable regions of the two or more movable bodies, in aggregate, may overlap all of the gas-permeable region of the valve seat when viewed along the first axis.

In another aspect of the apparatus, the movable center body and the movable intermediary body may be movable into a third configuration, where, in the third configuration, the movable intermediary body is positioned in a spaced-apart relationship from the valve seat and the movable center body is positioned proximate the movable intermediary body. The movable center body may be translatable along the first axis, independent of the movable intermediary body, for at least a portion of a transition between the second and third configurations.

In another aspect of the apparatus, the movable center body and the movable intermediary body may be movable into a third configuration, where, in the third configuration, the movable intermediary body is positioned proximate the valve seat and the movable center body is positioned in a spaced-apart relationship from the valve seat and intermediary body. The movable center body may be translatable along the first axis, independent of the movable intermediary body, for at least a portion of a transition between the first and third configurations. The movable center body and the movable intermediary bodies may be translatable in unison along the first axis for at least a portion of the transition between the second and third configurations.

In another aspect of the apparatus, the movable center body may have a disc shape. The movable intermediary body may have a ring shape. The gas-permeable region of the valve seat may have a disc shape.

In another aspect of the apparatus, the first configuration may provide a maximum flow restriction condition and the second configuration may provide a minimum flow restriction condition. The movable center body may travel a distance of X along the first axis when moving from the first configuration to the second configuration. The movable intermediary body may travel a distance of Y along the first axis when moving from the first configuration to the second configuration. In such an implementation, the movable intermediary body may have a ring shape with an average radial width of A, where A is at most 125% of X minus Y.

In another aspect of the apparatus, the movable center body may travel a distance of X when moving from the first configuration to the second configuration. The valve seat may, in such cases, have a gas-impermeable region with an average radial width of A and A is at most 125% of X.

In another aspect of the apparatus, the first configuration may be a maximum flow restriction condition and the multi-stage poppet valve may be gas-permeable in the maximum flow restriction condition.

In another aspect of the apparatus, when the multi-stage poppet valve is in the maximum flow restriction condition, there may be one or more gaps between respective pairs of the valve seat, the movable intermediary body, and the movable center body.

In another aspect, the apparatus may include a semiconductor processing chamber at least partly enclosing a volume having an average lateral cross-sectional dimension, a process gas delivery system configured to introduce one or more process gases into the semiconductor processing chamber, and a vacuum foreline in fluidic communication with the semiconductor processing chamber. The multi-stage poppet valve may be fluidically interposed between the process gas delivery system and the vacuum foreline, the movable intermediary body may be configured to translate a first distance between the first configuration, in which the movable intermediary body is proximate to the valve seat, and the second configuration, in which the movable intermediary body is positioned away from valve seat by the first distance. The movable intermediary body may have an average lateral cross-sectional dimension, and the movable center body may be configured to translate, relative to the movable intermediary body, a second distance between the first configuration, in which the movable center body is proximate to the gas-permeable of the movable intermediary body, and the second configuration, in which the movable center body is positioned away from the valve seat by the second distance and away from the movable intermediary body by the second distance minus the first distance. The movable center body may have an average lateral cross-sectional dimension, and the first distance may be between 35% and 65% of the average lateral cross-sectional dimension of the volume of the semiconductor processing chamber less the average lateral cross-sectional dimension of the movable intermediary body. The second distance may be between 35% and 65% of average lateral cross-sectional dimension of the movable intermediary body less the average lateral cross-sectional dimension of the movable center body.

In another aspect of the apparatus, the first distance may be between 75% and 125% of the second distance.

In another aspect of the apparatus, at least a portion of the semiconductor processing chamber may be cylindrical and may have a diameter equal to the average lateral cross-sectional dimension of the semiconductor processing chamber.

In another aspect of the apparatus, the movable intermediary body may be ring-shaped and the movable center body may be circular.

In another aspect, the apparatus may further include at least one turbomolecular pump fluidically coupled to the vacuum foreline.

In another aspect, the apparatus may further include a semiconductor processing chamber, a process gas delivery system configured to introduce one or more process gases into the semiconductor processing chamber, and a vacuum foreline in fluidic communication with the semiconductor processing chamber. The first configuration may include a maximum flow restriction condition. The second configuration may include a minimum flow restriction condition. When the movable intermediary body is in the second configuration, there may be a first minimum cross-sectional area between the movable intermediary body and the semiconductor processing chamber and there may be a second minimum cross-sectional area between the movable intermediary body and the valve seat. The first minimum cross-sectional area may be between 75% and 125% of the second minimum cross-sectional area. When the movable intermediary body is in the second configuration and the movable center body is in the second configuration, there may be a third minimum cross-sectional area between the movable center body and the semiconductor processing chamber and there may be a fourth minimum cross-sectional area between the movable center body and the gas-permeable region of the movable intermediary body. The third minimum cross-sectional area may be between 75% and 125% of the sum of the second minimum cross-sectional area and the fourth minimum cross-sectional area.

In another aspect, the apparatus may further include at least one turbomolecular pump fluidically coupled to the vacuum foreline.

In another aspect, an apparatus may be provided that may include a semiconductor processing chamber including a substrate support, where the semiconductor processing chamber has chamber walls that define a first volume at and above the substrate support and that define a second volume below the substrate support, a process gas delivery system configured to introduce one or more process gases into the semiconductor processing chamber, a vacuum foreline in fluidic communication with the first and second volumes of the semiconductor processing chamber, and a valve fluidically interposed between the process gas delivery system and the vacuum foreline, where the second volume has an average horizontal cross-sectional width, the valve has a valve throat with an average horizontal cross-sectional width, and the average horizontal cross-sectional width of the valve throat is between 85% and 100% of the average horizontal cross-sectional width of the second volume.

In another aspect of the apparatus, the valve may include a butterfly vent having at least a first body and a second body, where the first and second bodies may be configured to be transitionable between at least first and second configurations relative to each other through rotation of one or both the first and second bodies about a rotation axis. In the first configuration, gas-permeable regions of the first body may be in a state of maximum overlap with gas-permeable regions of the second body. In the second configuration, the gas-permeable regions of the first body may be in a state of maximum overlap with gas-impermeable regions of the second body and the gas-permeable regions of the second body may be in a state of maximum overlap with gas-impermeable regions of the first body.

In another aspect of the apparatus, the valve may have an iris valve having movable blades configured to be transitionable between a first configuration in which the movable blades are at least partially recessed under a perimeter of the iris valve and a second configuration in which the movable blades are extended into a central region of the iris valve.

### BRIEF DESCRIPTION OF THE DRAWINGS

FIG. 1 is a schematic diagram of an example semiconductor processing system for performing etch, deposition, and other operations according to some implementations.

FIG. 2 is a perspective view of a multi-stage poppet valve according to some implementations.

FIG. 3A is a cross-sectional side view and FIG. 3B is a cross-sectional perspective view of a semiconductor processing system including a high-conductance multi-stage poppet valve according to some implementations.

FIG. 4 is a cross-sectional side view of a semiconductor processing system including a high-conductance multi-stage poppet valve according to some implementations.

FIG. 5 is a cross-sectional side view of a semiconductor processing system including a high-conductance multi-stage poppet valve according to some implementations.

FIGS. 6A, 6B, and 6C illustrate an example of a multi-stage poppet valve in various states of operation according to some implementations.

FIGS. 7A and 7B illustrate an example of a multi-stage poppet valve in various states of operation according to some implementations.

FIG. 7C illustrates an example of a multi-stage poppet valve in various states of operation according to some implementations.

FIGS. 8A, 8B, 8C, and 8D illustrate an example of a multi-stage poppet valve according to some implementations.

FIGS. 8E, 8F, and 8G illustrate an example of a multi-stage poppet valve in various states of operation according to some implementations.

FIGS. 9A, 9B, and 9C illustrate examples of high-conductance vacuum valves according to some implementations.

FIGS. 10A, 10B, 10C, 10D, 10E, and 10F illustrate examples of a multi-stage poppet valve according to some implementations.

FIG. 11 is a schematic diagram of an example control module for controlling semiconductor fabrication tools including vacuum pumping systems and vacuum valves according to some implementations.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments. The techniques and devices disclosed herein may be implemented in a variety of ways, including, but not limited to, the various implementations described below. It is to be understood that one of ordinary skill in the art may use the techniques and devices described herein to produce other implementations consistent with the information disclosed in this document, and that such alternative implementations are also to be considered as within the scope of this disclosure.

### Terminology

The following terms are used throughout the instant specification:

The terms “semiconductor wafer,” “wafer,” “substrate,” “wafer substrate” and “partially fabricated integrated circuit” may be used interchangeably. Those of ordinary skill in the art understand that the term “partially fabricated integrated circuit” can refer to a semiconductor wafer during any of many stages of integrated circuit fabrication thereon. A wafer or substrate used in the semiconductor device industry typically has a diameter of 200 mm, or 300 mm, or 450 mm. This detailed description assumes the embodiments are implemented on a wafer. However, the disclosure is not so limited. The work piece may be of various shapes, sizes, and materials, including, for example, large rectangular substrates used in manufacturing display screens. Besides semiconductor wafers, other work pieces that may take advantage of the disclosed embodiments include various articles such as printed circuit boards, magnetic recording media, magnetic recording sensors, mirrors, optical elements, micro-mechanical devices and the like.

A “semiconductor device fabrication operation” or “fabrication operation,” as used herein, is an operation performed during fabrication of semiconductor devices. Typically, the overall fabrication process includes multiple semiconductor device fabrication operations, each performed in its own semiconductor fabrication tool such as a plasma reactor, an electroplating cell, a chemical mechanical planarization tool, a wet etch tool, and the like. Categories of semiconductor device fabrication operations include subtractive processes, such as etch processes and planarization processes, and additive processes, such as deposition processes (e.g., physical vapor deposition, chemical vapor deposition, atomic layer deposition, electrochemical deposition, electroless deposition). In the context of etch processes, a substrate etch process may include processes that etch a mask layer or, more generally, processes that etch any layer of material previously deposited on and/or otherwise residing on a substrate surface. Such etch processes may etch a stack of layers in the substrate.

“Manufacturing equipment” or “fabrication tool” refers to equipment in which a manufacturing process takes place. Manufacturing equipment may include a processing chamber in which the workpiece resides during processing. Typically, when in use, manufacturing equipment performs one or more semiconductor device fabrication operations. Examples of manufacturing equipment for semiconductor device fabrication include subtractive process reactors and additive process reactors. Examples of subtractive process reactors include dry etch reactors (e.g., chemical and/or physical etch reactors), wet etch reactors, and ashers. Examples of additive process reactors include chemical vapor deposition reactors, and atomic layer deposition reactors, physical vapor deposition reactors, and electroplating cells.

It is to be understood that, as used herein, “hermetic” and “gas impermeable” refers to a structure or an interface that is generally gastight under normal operating conditions. A hermetic seal may, nonetheless, permit an acceptable minimum amount of gas communication across the seal. For example, a high-vacuum gate valve may have a leak rate on the order of 10⁻⁸ to 10⁻⁹ Torr-liters/sec. Such leak rate amounts are typically defined and budgeted during equipment design, and are verified using methods described in, for example, standards such as SEMI E-16. It is to be understood that while the seals and valves used to maintain the pressure environments discussed herein may not provide a theoretically perfect seal due to such negligible leak rates, such seals and valves are still described as “preventing” fluid flow when closed (i.e., as being “gas impermeable”). As used herein, “hermetic” and “gas impermeable” refers to a structure or an interface with a leak rate no greater than 10⁻⁴ liters/sec when at a pressure differential of at least 100 Torr and using Helium as a tracer gas. In contrast, “gas permeable” refers to a structure or an interface that has a leak rate greater than 10⁻⁴ liters/sec when at a pressure differential of no more than 100 Torr and using Helium as a tracer gas.

### Introduction and Context

Semiconductor wafer processes typically require exacting environmental conditions within a semiconductor processing chamber. Gas composition, density, pressure, temperature, etc. may all be required to be within certain pre-established ranges in order to successfully process a semiconductor wafer. Providing these environmental conditions may require inducing various kinds of gas flow, e.g., evacuating gas from a portion of a semiconductor tool to produce or maintain a particular low-pressure, e.g., vacuum, environment.

Gas flow, in general, can be categorized as falling within one of three categories: viscous flow, transitional flow, and molecular flow. Viscous flow generally refers to fluid flow under conditions where the mean free path of the molecules in the fluid flow is small in comparison with, for example, the smallest transverse section of a duct through which the fluid flows. In the case of fluid flow through a large chamber, viscous flow may be characterized by the mean free path of the molecules being small in comparison to the smallest overall internal dimension of the chamber. In viscous flow, for example, the density of gas molecules is generally high enough that many of the gas molecules collide with other gas molecules in the flow before colliding with, for example, the chamber walls. As a result, the mean free path of the gas molecules, i.e., the average distance that a gas molecule in the fluid flow travels before colliding with another molecule, is considerably shorter than the internal dimensions of the volume within which the flow occurs. In viscous flow, the flow of some portions of a substance may cause other, contiguous portions of the substance to exhibit similar flow characteristics.

Molecular flow generally refers to fluid flow under conditions where the mean free path of the molecules in the fluid flow is much greater than a characteristic system dimension, for example, the smallest transverse section of a duct through which the fluid flows. In the case of fluid flow through a large chamber, the mean free path may be much greater than, for example, the smallest overall internal dimension of the chamber. In molecular flow, the density of the gas molecules is sufficiently low that many of the gas molecules will collide with the chamber walls before colliding with another gas molecule. Due to the infrequency of molecule-molecule collisions in molecular flow, the flow of one gas molecule is unlikely to have much of an impact on other gas molecules in the flow. A flow’s characterization as viscous or molecular at a given temperature is largely dependent on the density of the gas in the flow. For a given temperature, viscous flows occur at much higher pressures, e.g., 1 mTorr to 760 Torr, than molecular flows, e.g., 0.1 mTorr and below.

Transitional flow generally refers to a transitional regime between viscous flow and molecular flow. In transitional flow, both wall collisions (e.g., the typical collisions in molecular flow) and intermolecular collisions (e.g., the typical collisions in viscous flow) are influential in determining flow characteristics.

For a vacuum pumping system, an important property is the conductance, which is the gas volume flow rate between two points along the flow path divided by the pressure drop between those two points. Since the flow path of each gas molecule in the molecular flow regime is, statistically speaking, free from influence from other gas molecules, vacuum pumps removing gas from a chamber while operating in the molecular flow regime rely, in a general sense, on gas molecules ricocheting off of the chamber walls until they happen to ricochet in a manner that leads them into the throat of the vacuum pump. Thus, a vacuum pump, particularly when operating in the molecular flow region, sees significant performance benefits (e.g., higher conductance) when its throat is relatively large (in cross-sectional area) and when there is a relatively unobstructed path between the chamber and the vacuum pump’s throat. As a result, it is often desirable to increase or maximize the size of a vacuum valve, at least in terms of cross-sectional area, in order to increase or maximize the conductance.

A vacuum pumping system may include one or more vacuum valves fluidically interposed between one or more vacuum pumps and a semiconductor processing chamber. The vacuum valve(s) may facilitate regulation of pressure within the semiconductor processing chamber and/or gas flow rates through the semiconductor processing chamber and the vacuum pumping system. In some embodiments, the vacuum valve(s) may hermetically isolate the semiconductor processing chamber and the vacuum pumping system from each other when in a closed state.

One type of vacuum valve is a poppet valve. A poppet valve generally includes a valve seat (which has a valve throat through which gases flow) and a movable plug. To close the valve and block or reduce gas flow rates through the valve throat, the movable plug is moved toward and eventually pressed against, or seated within, the valve seat. To open the valve and permit or increase gas flow rates through the valve throat, the movable plug is moved away from the valve seat. The movement of the plug is generally translational movement along an axis that is perpendicular, for example, to the surface of the valve seat against which the plug is pressed.

When increasing the conductance of a vacuum pumping system utilizing a poppet valve, it is generally desirable to increase the size of the poppet valve through which the vacuum pump draws gas in order to improve the conductance to the vacuum pumping system; this, in turn, generally also causes the movable plug to correspondingly increase in size. However, as the plug of the poppet valve gets larger, clearance between the plug and the inner walls of the processing chamber may shrink and eventually become a bottleneck to system conductance (e.g., increasing the size of the poppet valve beyond a certain point actually acts to reduce system conductance in comparison to some smaller-sized poppet valves).

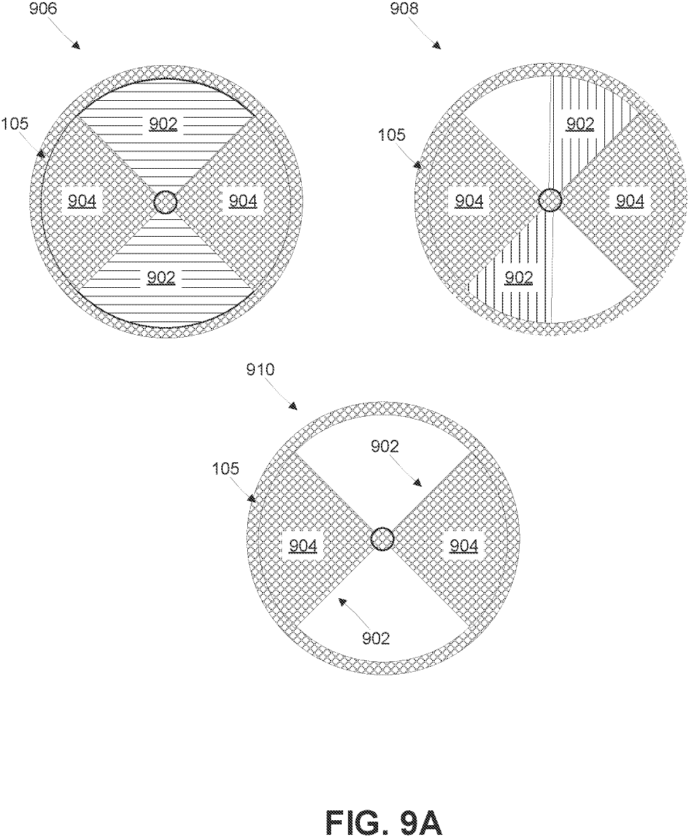

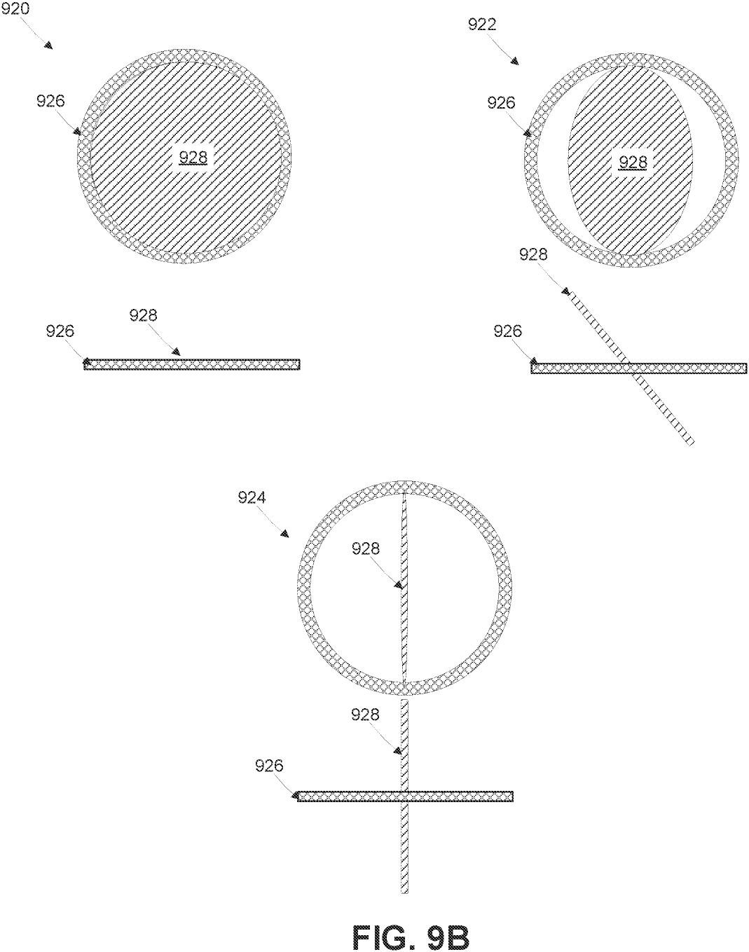

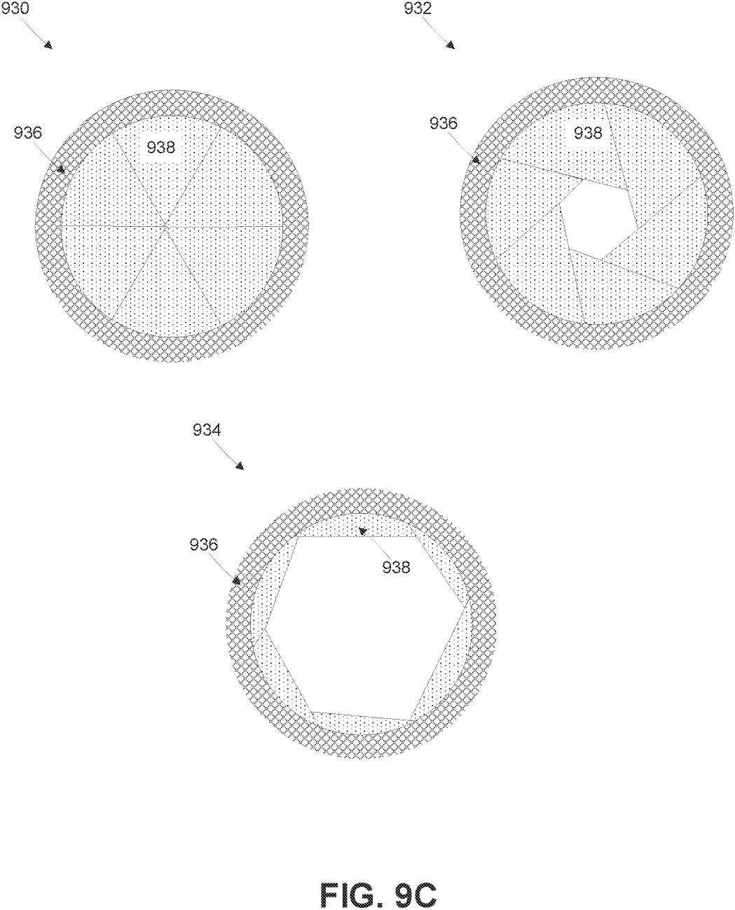

The present disclosure relates to high-conductance vacuum valves for semiconductor processing systems. A high-conductance vacuum valve may, in some embodiments, be a multi-stage poppet valve. The multi-stage poppet valve may provide a higher level of conductance than a single-stage poppet valve, particularly when the poppet valves are constrained by the dimensions of a semiconductor processing chamber and the vacuuming pumping system is operating in a molecular flow regime. High-conductance vacuum valves may, alternatively, be implemented with another style of valve such as a butterfly vent, butterfly valve, and/or an iris valve, as will be discussed in more detail in connection with FIGS. 9A, 9B, and 9C.

### Semiconductor Processing Systems with a High-Conductance Vacuum Valve

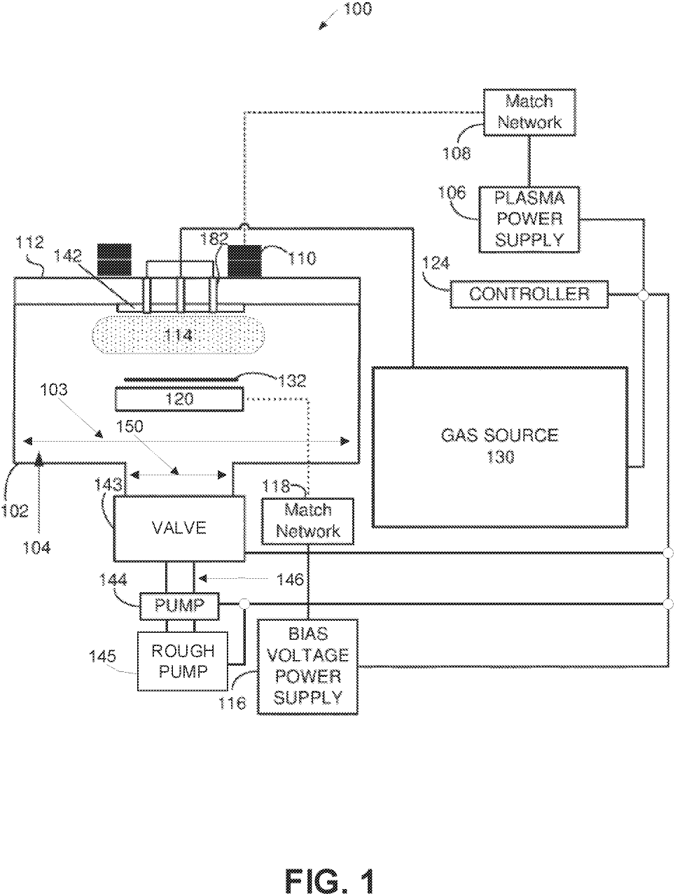

FIG. 1 schematically illustrates an example of a tool 100 (e.g., a semiconductor processing system). The tool 100 may be a fabrication tool including a semiconductor processing chamber 102, which may include a plasma processing confinement chamber 104 therein. In some other embodiments, tool 100 may be a metrology tool or other tool involved in semiconductor fabrication. A plasma power supply 106, tuned by a match network 108, supplies power to a transformer-coupled-plasma (TCP) coil 110 located near a power window 112 to create a plasma 114 in the plasma processing confinement chamber 104 by providing for wireless power transfer to the process gases within the chamber 104 via inductive coupling. The TCP coil (upper power source) 110 may be configured to produce a diffusion profile within the plasma processing confinement chamber 104. For example, the TCP coil 110 may be configured to generate a toroidal power distribution in the plasma 114. The power window 112, which may be generally transmissive to radio-frequency energy, is provided to separate the TCP coil 110 from the plasma processing confinement chamber 104 while allowing energy to pass from the TCP coil 110 to the plasma processing confinement chamber 104. A wafer bias voltage power supply 116 tuned by a match network 118 provides power to an electrode in the form of a substrate support 120 to set the bias voltage on the substrate 132 which is supported by the substrate support 120. A controller 124 sets points for the plasma power supply 106, gas source/gas source 130 (e.g., a processing gas delivery system), wafer bias voltage power supply 116, valve 143, pump 144, and optional rough pump 145.

The gas source 130 is in fluidic connection with the semiconductor processing chamber 102 through gas inlets 182 in a shower head 142. The gas inlets 182 may be located in any advantageous location in the plasma processing confinement chamber 104, and may take any form for injecting gas. The process gases and by products are removed from the plasma process confinement chamber 104 via a pressure control valve 143 and a pump 144, which also serve to maintain a particular pressure within the plasma processing confinement chamber 104.

The vacuum pumps 144 and 145 may be fluidically coupled to the semiconductor processing chamber 102 and may be used to draw out process gases from the semiconductor processing chamber 102 and to maintain a certain pressure within the semiconductor processing chamber 102 The vacuum pumps 144 and 145 may be fluidically coupled to the valve 143 through a vacuum foreline 146. The valve 143 may control the amount of conductance between the vacuum pump 144 and the semiconductor processing chamber 102, and thus help control the level of vacuum within the semiconductor processing chamber 102. In some implementations, the vacuum pump 145 can include a one or two stage mechanical dry pump and/or turbomolecular pump. In some implementations, the vacuum pump 144 may be activated after each time a deposition or etch operation is completed to purge the semiconductor processing chamber 102. In some implementations, the vacuum pump 144 may run during deposition, etch, or other fabrication operations, while valve 143 is used to modulate the level of vacuum within chamber 102. The vacuum pump 144 is fluidically connected to the semiconductor processing chamber 102 and may serve to remove etch gases, deposition precursors, and reaction byproducts from the semiconductor processing chamber 102. In some embodiments, the pump 144 is a high vacuum pump such as a turbomolecular pump. The output of pump 144 may be coupled to a rough pump 145. The output of rough pump 145 may be vented to atmosphere or another gas sink.

The tool 100 may be coupled to facilities (not shown) when installed in a clean room or a fabrication facility. Facilities include plumbing that may provide processing gases, vacuum, temperature control, and environmental particle control. In some such embodiments, pump 144 and/or pump 145 may be a part of the facility and may be shared by multiple tools 100. As an example, valves 143 of multiple fabrication tool 100 may be fluidically coupled to one or more common pumps 144 and/or pumps 145 through a network of vacuum forelines 146 (which may branch as needed). Thus, these facilities may be coupled to the tool 100 when installed in the target fabrication facility. Additionally, the tool 100 may be coupled to a transfer chamber that allows robotics to transfer substrates into and out of the semiconductor processing chamber 102 using automation.

In some embodiments, the tool 100 may be a multi-station tool (e.g., multiple fabrication stations operating on multiple wafers and sharing a common semiconductor processing chamber). In some such embodiments, the semiconductor processing chamber may have an even larger cross-section and the size of valve 143 can be correspondingly scaled up. In some other such embodiments, there may be a separate valve 143 for each station in the multi-station tool. The teachings herein can thus also apply to multi-tool arrangements.

As shown in FIG. 1, the semiconductor processing chamber 102 may have a width 103 and the valve 143 may have a width 150. Valve 143 may be configured to provide a high level of conductance (e.g., a relatively high gas flow rate and/or a relatively low pressure drop through the valve). In general, larger valves have larger throats (e.g., cross-sectional areas through which gas can flow) and thus have greater conductance than similar smaller valves. Thus, it is generally desirable to increase the size of a valve in order to increase conductance (e.g., increase the width 150). This general trend can break down for certain types of valves when clearance shrinks between the enlarged valves and adjacent structures (such as the walls of the semiconductor processing chamber 102), thereby limiting conductance. As an example, if valve 143 were a single-stage poppet valve, with a plug that moves perpendicularly to the width 150 of the valve and valve 143 were enlarged so that its width 150 matched the width 103 of the semiconductor processing chamber, there would be no clearance between the plug of the poppet valve and the walls of the semiconductor processing chamber, thus gas flow through the poppet valve would be severely limited or even blocked even when the poppet valve is open.

To address such problems, the present inventors conceived of high-conductance vacuum valves such as a multi-stage poppet valve. The multi-stage poppet valve may include a plug that is split into a movable center body and a movable intermediary body. By splitting the plug into a movable center body and a movable intermediary body, the potential overall conductance of the poppet valve is increased, relative to a single-stage poppet valve. As an example, the movable intermediary body can have an outer diameter as large as the single-stage plug, providing a large throat while maintaining clearance with adjacent structures (such as the walls of the semiconductor processing chamber 102). The movable center body, in its open configuration, may expose an additional gas-permeable region of the movable intermediary body, raising the potential overall conductance beyond what is achievable with a single-stage poppet valve.

### A Multi-Stage Poppet Valve

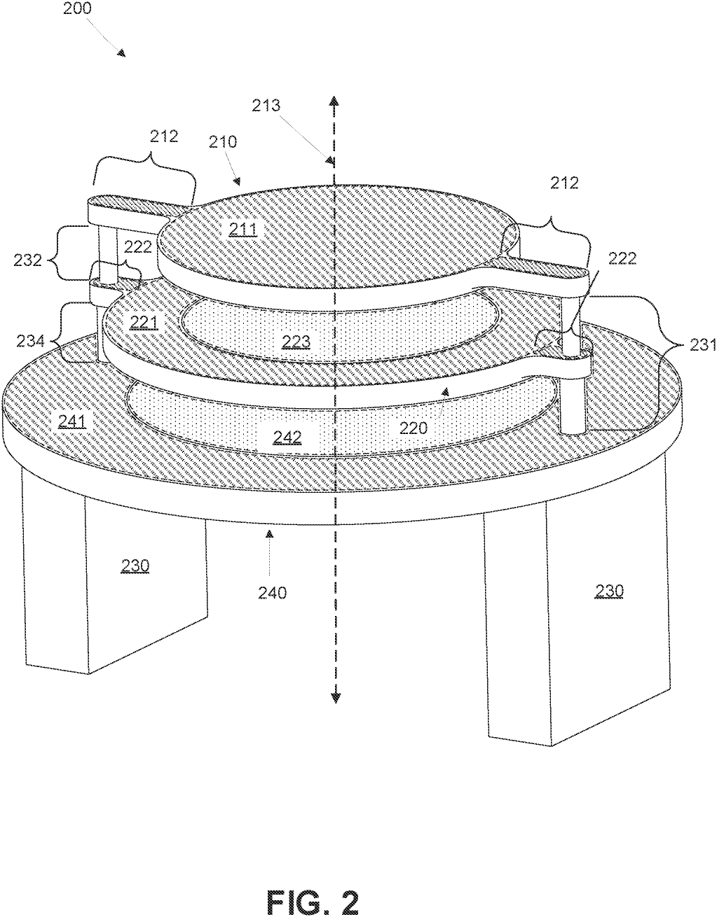

FIG. 2 is a perspective view of an example multi-stage poppet valve 200, which may be used as valve 143 in tool 100. Multi-stage poppet valve 200 may include a valve seat 240 and two or more movable bodies such as movable center body 210 and movable intermediary body 220. If desired, valve 200 may include additional movable bodies. As an example, valve 200 could include a movable center body 210 and multiple intermediary bodies (e.g., a center disc, a first ring surrounding the center disc, a second ring surrounding the first ring, a third ring surround the second ring, etc.). In general, increasing the number of movable bodies in this manner increases the conductance potential of the overall valve 200. However, increasing the number of movable bodies in this manner may also require additional vertical clearance for each additional movable body, as will become evident from the discussion below; space constraints may thus drive selection of a particular number of movable bodies.

The movable center body 210 may include a gas-impermeable region 211; in the depicted example, the gas-impermeable region 211 of the movable center body 210 is a circular disk, although other shapes are potentially usable as well if desired. One or more wings such as wings 212 can extend from the movable center body 210 and mechanically couple the movable center body 210 to one or more actuator shafts or other structures capable of being translated vertically so as to also translate the movable center body 210 vertically. The wings 212 may be formed from an integral extension of the movable center body 210 (e.g., the wings and movable center body 210 may be a single integral piece) or the wings 212 may be formed of separate structures attached to the movable center body. The wings 212 may extend beyond the perimeter of the gas-permeable region 242 of the valve seat 240 (e.g., the opening formed by the valve seat 240). There may be any desired number of wings 212, including a single wing 212. The movable center body 210 may translate along a first axis 213, normal to the plane in which the movable center body 210 lies.

The movable intermediary body 220 may include gas-permeable regions 223 (e.g., the opening in the center of the ring shape of FIG. 2, indicated by cross-hatching) and gas-impermeable regions 221 (e.g., in the solid regions of the ring shape of FIG. 2, indicated by a dashed outline). The gas-permeable regions 223 and gas-impermeable regions 221 extend, in the perspective of FIG. 2, beneath moveable center body 210. One or more wings such as wings 222 can extend from the movable intermediary body 220 and mechanically couple the movable intermediary body 220 to one or more actuator shafts or other structures capable of being translated vertically so as to also translate the movable intermediary body 220 vertically. The wings 222 may be formed from an integral extension of the movable intermediary body 220 (e.g., the wings and movable intermediary body 220 may be a single integral piece) or the wings 222 may be formed of separate structures attached to the movable intermediary body 220. The wings 222 may extend beyond the perimeter of the gas-permeable region 242 of the valve seat 240 (e.g., the opening formed by the valve seat 240). There may be any desired number of wings, including a single wing. The movable intermediary body 220 may also be translatable along the first axis 213.

As will be discussed in further detail below, the movable center body 210 is translatable along the first axis 213 into a first position, a second position, and one or more positions therebetween (e.g., a continuum of additional positions between the first and second positions). In the first position, the gas-impermeable region 211 of the movable center body 210 is positioned proximate the gas-permeable regions 223 of the movable intermediary body 220, thus restricting conductance to a first amount (which may be as low as zero conductance). In the second position, the movable center body 210 is positioned in a spaced-apart location along the first axis 213, relative to the movable intermediary body 220. In the one or more positions between the first and second positions, the movable center body is positioned somewhere between the first and second positions (e.g., in a partially spaced-apart location relative to the movable intermediary body 220 along the first axis 213). When the movable center body 210 is translated away from the movable intermediary body (in the second position or positions between the first and second positions), a gap exists between the movable center body 210 and the movable intermediary body 220 when viewed along a direction perpendicular to the first axis 213. Gas from within the semiconductor processing chamber 102 can flow throw these gaps.

As will be discussed in further detail below, the movable intermediary body 220 is translatable along the first axis 213 into a first position, a second position, and one or more positions therebetween (e.g., a continuum of additional positions between the first and second positions). In the first position, the gas-impermeable regions 221 of the movable intermediary body 220 are positioned proximate the gas-permeable regions 242 of the valve seat 240 (whose position is shown in FIG. 2 via a dashed line), thus restricting conductance between the movable intermediary body 220 and the valve seat 240 to a first amount (which may be as low as zero conductance in situations where the movable intermediary body 220 and the valve seat 240 contact each other). In the second position, the movable intermediary body 220 is positioned in a spaced-apart location along the first axis 213 relative to the valve seat 240. In the one or more positions between the first and second positions, the movable center body is positioned somewhere between the first and second positions (e.g., in a partially spaced-apart location relative to the valve seat 240 along the first axis 213). When the movable intermediary body 220 is translated away from the valve seat 240 (in the second position or positions between the first and second positions), gaps exist between the movable intermediary body 220 and the valve seat 240 when viewed along a direction perpendicular to the first axis 213. Gas from within the semiconductor processing chamber 102 can flow throw these gaps. In some embodiments, the gas-impermeable regions of the movable bodies (e.g., gas-impermeable regions 211 and 221) may, in aggregate, overlap at least 90%, but less than 100%, of the gas-permeable region 242 of the valve seat 240 when viewed along the first axis 213. In some other embodiments, the gas-impermeable regions of the movable bodies (e.g., gas-impermeable regions 211 and 221) may, in aggregate, overlap 100% of the gas-permeable region 242 of the valve seat 240 when viewed along the first axis 213.

The multi-stage poppet valve 200 may also include one or more actuators 230. In general, there may be any desired number of actuators and the actuators may be placed in any desired locations. In the example of FIG. 2, the actuators 230 are linear actuators that translate respective shafts 231, which in turn translate the movable bodies along the first axis 213. The actuators 230 may be any suitable types of actuators such as linear actuators, rotary actuators, stepper actuators, servo actuators, etc. The actuators 230 may, as examples, be electromechanical, electromagnetic, pneumatic, or hydraulic. Shafts 231, in some arrangements, are stepped shafts. In particular, shafts 231 may have a first portion 232 and a second portion 234, where the second portion 234 is larger in cross-section than the first portion 232. Additionally, the wings 222 of the movable intermediary body 220 may be configured such that the first portion 232 passes through an opening, notch, cut-out, recess, or the like in the wings 222 without binding or, in many cases, contacting the wings 222 when the shaft 231 is translated along the first axis 213, while the second portion 234 is too large to fit through the opening in the wings 222. As will be discussed in further detail below, this type of configuration allows for semi-independent movement of the movable center body 210 and the movable intermediary body 220.

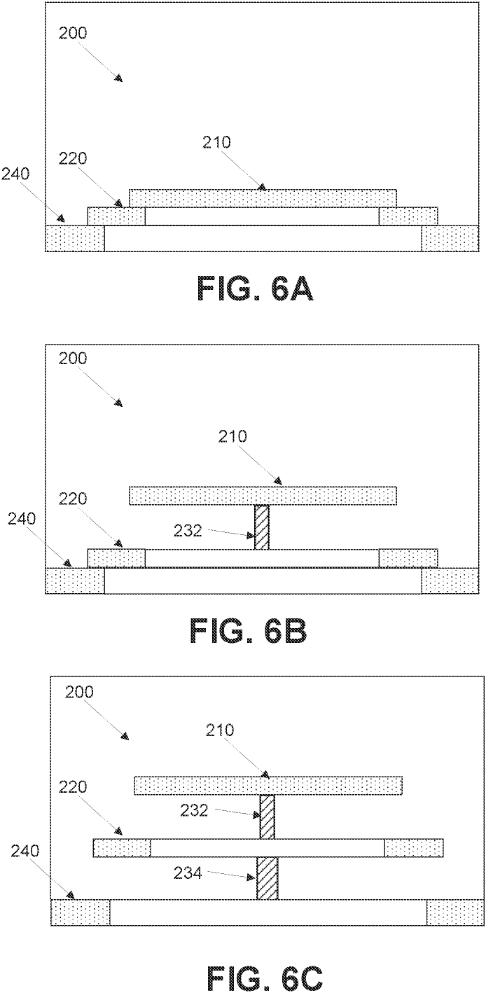

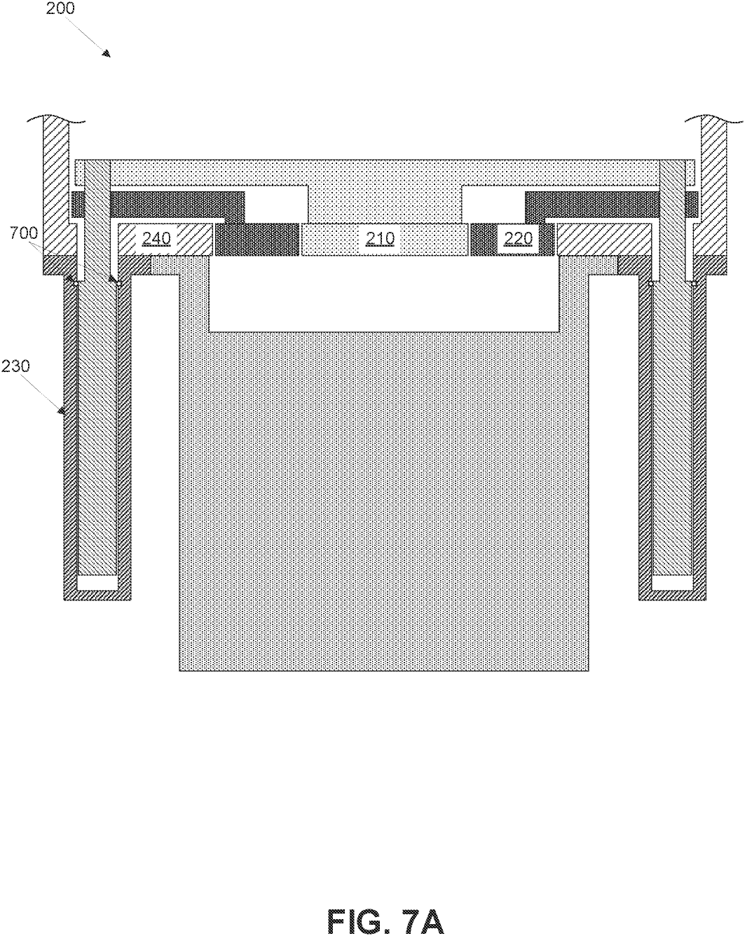

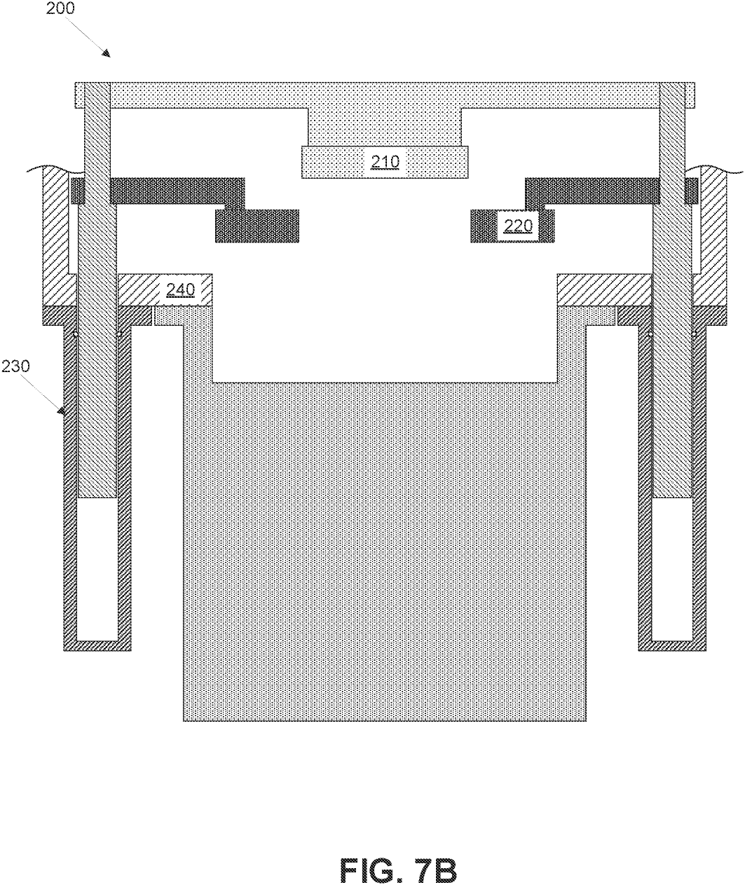

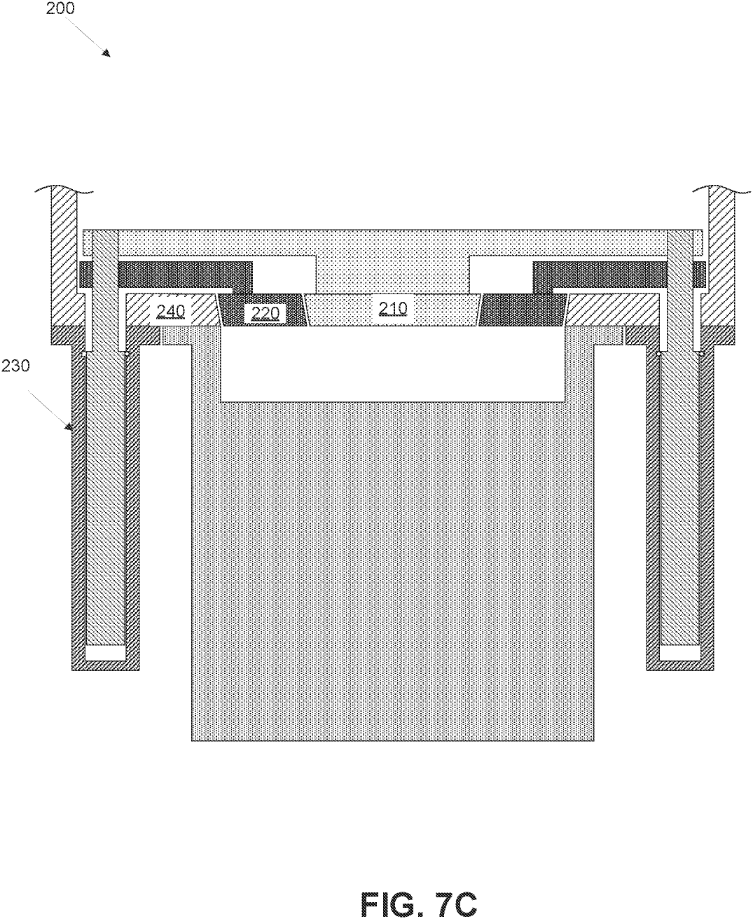

An example of the movement of the multi-stage poppet valve 200, in embodiments utilizing stepped shafts 231, is illustrated in FIGS. 6A, 6B, and 6C. While FIGS. 6A, 6B, and 6C illustrate the movable bodies stacking together and on top of the valve seat 240, this is merely one arrangement. An alternative arrangement, with the movable bodies and valve seat nesting together is illustrated in FIGS. 7A, 7B, and 7C.

As shown in FIG. 6A, the multi-stage poppet valve 200 may be placed into a first configuration (e.g., a fully closed state) by retracting of the stepped shafts 231 into actuators 230. In the first configuration, the multi-stage poppet valve 200 may be in a minimum conductance state, which may generally be gas-impermeable or which may generally be slightly gas-permeable. In embodiments in which the multi-stage poppet valve 200 is gas-permeable in its first configuration, the conductance of the multi-stage poppet valve 200 in the first configuration may be orders of magnitude less than the conductance of the multi-stage poppet valve 200 in a second configuration (e.g., a fully opened state).

As shown in FIG. 6B, the multi-stage poppet valve 200 may be placed into a third configuration (e.g., a partially opened state) by partially extending the stepped shafts 231 out of actuators 230 such that the movable center body 210 is raised into a spaced-apart relationship with respect to the movable intermediary body 220. As the thinner portion 232 of the stepped shafts 231 passes through the movable intermediary body 220, the movable intermediary body remains proximate the valve seat during transitions between the first and third configurations (e.g., between the partially open state of FIG. 6B and the fully closed state of FIG. 6A).

As shown in FIG. 6C, the multi-stage poppet valve 200 may be placed into a second configuration (e.g., a fully opened state) by further extending the stepped shafts 231 out of actuators 230, such that the movable intermediary body 220 is raised into a spaced-apart relationship from the valve seat 240. As the thicker portion 234 of the stepped shafts 231 cannot pass through the moveable intermediary body 220, the thicker portion 234 of the stepped shafts 231 may engage with the movable intermediary body and cause it and the movable center body to move in unison during transitions between the third and second configurations (e.g., between the partially open state of FIG. 6B and the fully opened state of FIG. 6C).

The movable center body 210, movable intermediary body 220, any other movable bodies, and the valve seat may have any desired shape. In general, it may be desirable for these components of the valve 200 to be conformal with adjacent walls 106 of the semiconductor processing chamber 102, although it is noted that components or elements such as wings 212 and 222 and shafts 231 may not be conformal in the same manner. In other words, if the semiconductor processing chamber is cylindrical, it may be desirable for the movable bodies and valve seat of the valve 200 to also be cylindrical or circular in order to provide increased conductance, where a relatively uniform gaps exists between the semiconductor processing chamber and adjacent portions of the movable bodies and valve seat and where components such as wings 212 and 222 and shafts 231 may reside within such gaps). Similarly, if the semiconductor processing chamber is square or rectangular (at least in outline at the position of the valve 200), it may be desirable for the movable bodies and valve seat of the valve 200 to have a matching square or rectangular shape. Irregular shapes of the semiconductor processing chamber 102 and valve 200 components are also possible. In the example of FIG. 2, the movable center body 210 is primarily circular (excepting the wings 212), the movable intermediary body 220 is primarily ring-shaped (excepting the wings 220), and the valve seat is also contemplated as being ring-shaped (although omitted from FIG. 2). In general, the outer diameter of the movable center body 210 is contemplated as being approximately equal to that of the inner diameter of the movable intermediary body 220, while the outer diameter of the movable intermediary body 220 is contemplated as being approximately equal to that of the inner diameter of the valve seat. As will be discussed in further detail below, arrangements in which the movable center body 210 overlaps the movable intermediary body (e.g., in which the movable center body has a larger diameter than the inner diameter of the movable intermediary body) and/or in which the movable intermediary body overlaps the valve seat are contemplated. Additionally, arrangements in which the movable center body 210 nests within the movable intermediary body and/or in which the movable intermediary body nests within the valve seat are contemplated.

### A Semiconductor Processing Chamber with a Multi-Stage Poppet Valve

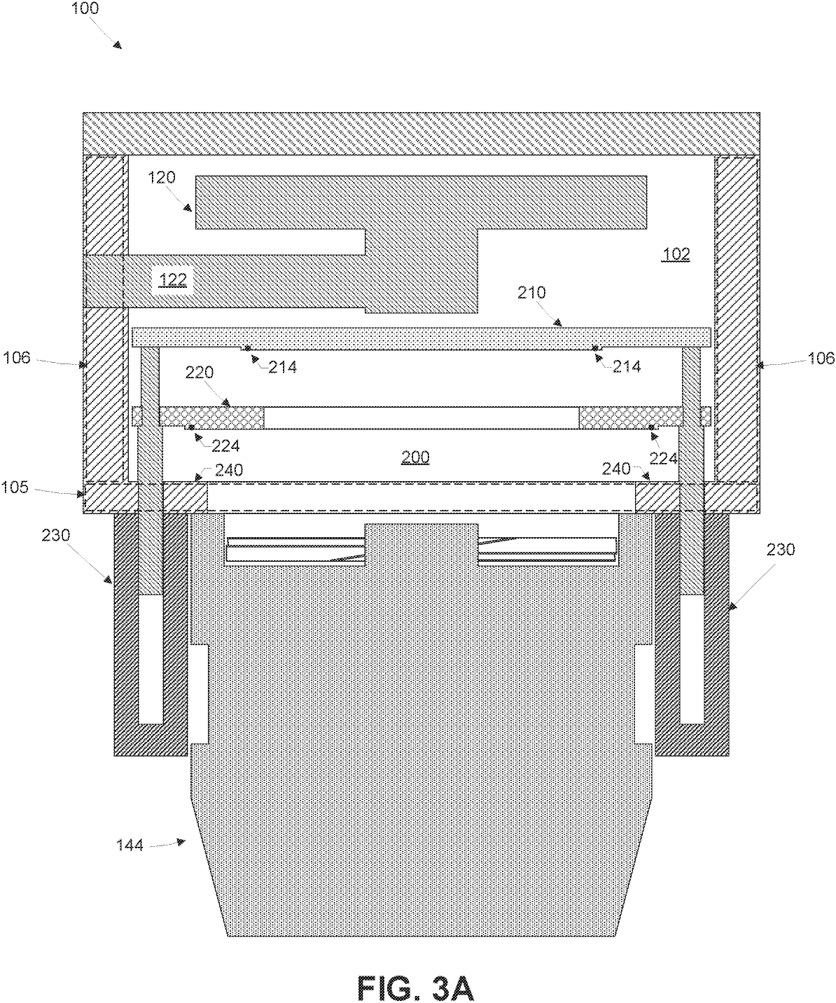

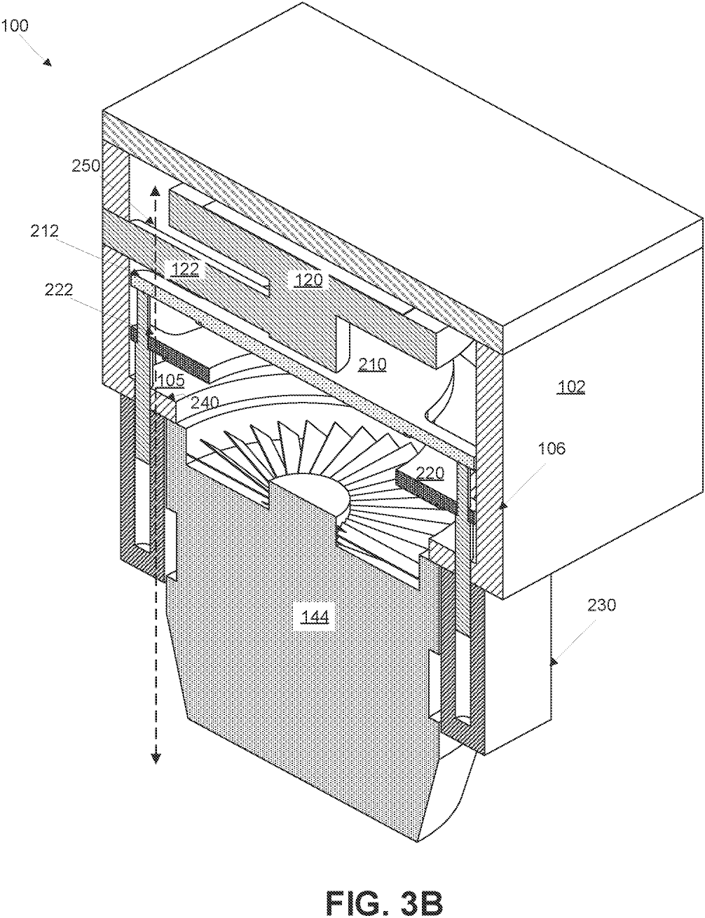

FIG. 3A is a cross-sectional side view and FIG. 3B is a cross-sectional perspective view of the multi-stage poppet valve 200 of FIG. 2 installed in tool 100 of FIG. 1.

Valve seat 240 may be formed, as shown in FIGS. 3A and 3B, by the floor 105 of the semiconductor processing chamber 102. The floor 105 is highlighted by a dashed line in FIG. 3A. If desired, valve seat 240 may be formed of a component separate from the floors 105 of the semiconductor processing chamber 102.

The substrate support 120 may be held in place by a substrate support arm 122. As shown in FIG. 3B, the substrate support arm 122 may be aligned with wings 212 and/or wings 222 of the movable bodies 210 and 220, respectively. In particular, when viewed from a perspective parallel to the first axis 213, the substrate support arm may overlap with the wings on at least one side of the movable bodies. As shown in FIG. 3B, the substrate support arm 122 and at least one wing 212 of movable body 210 and at least one wing 222 of movable body 220 can be aligned along a second axis 250 parallel to the first axis 213. Aligning the substrate support arm 122 with the wings 212 and 222 can help to further improve conductance through the system, as it reduces the total cross-sectional area in which gas flow is restricted by the presence of physical structures. In some embodiments, the tool 100 may have two or more substrate support arms 122 and some or all of the substrate support arms 122 may be similarly aligned with wings of the movable bodies.

The multi-stage poppet valve 200 may, if desired, include seals in some implementations. As examples, valve 200 may include a first seal 214 mounted to the movable center body 210 and a second seal 224 mounted to the movable intermediary body 220. When the movable center body 210 is positioned proximate the movable intermediary body 220, the first seal 214 may be in contact with both the movable intermediary body 220 and the movable center body 210. Similarly, when the movable intermediary body 220 is positioned proximate the valve seat 240, the second seal 224 may be in contact with both the movable intermediary body 220 and the valve seat 240. The first seal 214 may provide a hermetic seal between the movable intermediary body 220 and the movable center body 210 when the movable bodies are proximate and/or pressed against each other. The second seal 224 may provide a hermetic seal between the movable intermediary body 220 and the valve seat 240, when the movable intermediary body 220 is proximate and/or pressed against the valve seat 240.

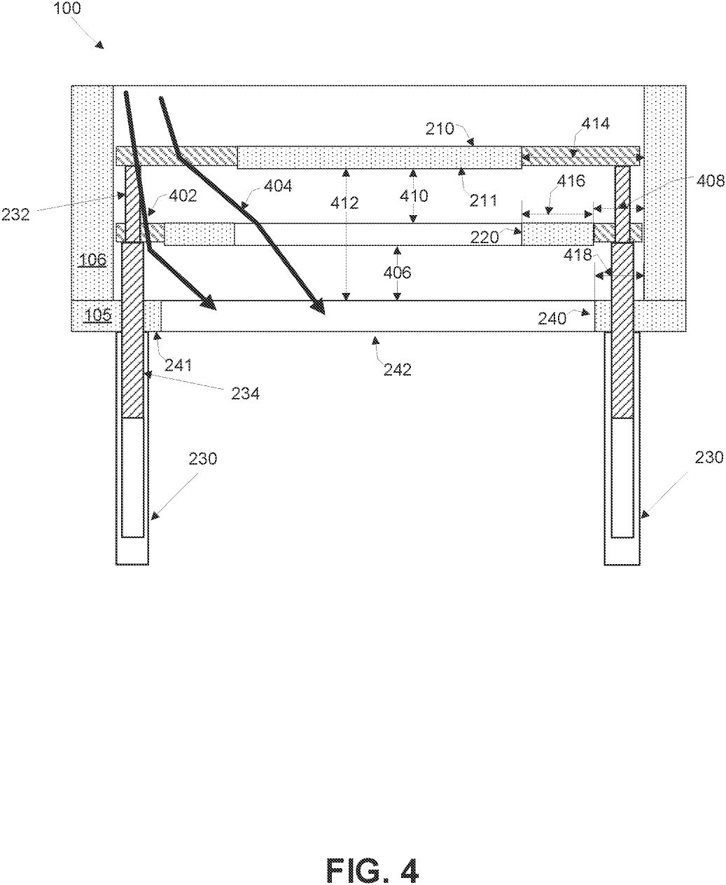

FIG. 4 illustrates the interplay between the sizes of various movable bodies and the clearances with the surrounding walls 106 and floors 105 of the semiconductor processing chamber. As discussed above, larger valves typically have a greater conductance than smaller valves, unless the valves become so large that there is insufficient clearance with surrounding structures in which case the effective conductance is limited or reduced. A multi-stage poppet valve 200 of the type disclosed herein is capable of achieving a greater conductance within the confines of a semiconductor processing chamber, as compared to the potential conductance of a single-stage poppet valve.

As shown in FIG. 4, when the multi-stage poppet valve 200 is in its fully open configuration, there are gas flow paths 402 and 404 that pass through the valve. The flow path 404 passes between the movable center body 210 and the movable intermediary body 220, while the flow path 402 passes between the movable intermediary body 220 and the valve seat 240. In order to increase the conductance of the valve 200 in its fully open configuration, it may be desirable to increase the total cross-sectional area provided by flow paths 402 and 404.

The conductance of flow path 402, when the movable intermediary body 220 is in its fully opened configuration, is primarily determined by three dimensions, the outer radius of the movable intermediary body 220, the distance 406 between the movable intermediary body 220 and the valve seat 240, and the distance 408 between the movable intermediary body 220 and the walls 106 of the semiconductor processing chamber 102 (assuming the valve is in its fully opened configuration). The distance 406 may represent the gap between the movable intermediary body 220 and the valve seat 240, when the movable intermediary body 220 is in its fully open position. The distance 408 can be measured perpendicular to the first axis 213.

Similar to the conductance of flow path 402, the conductance of flow path 404, when the movable center body 210 is in its fully opened configuration, is primarily determined by three dimensions, the radius of the movable center body 210, the distance 410 between the movable center body 210 and the movable intermediary body 220, and the distance 414 between the movable center body 210 and the walls 106. Additionally, it is noted that both flow paths 402 and 404 have to pass through the gap determined by distance 414, when both movable bodies 210 and 220 are in their fully opened configurations. As a result, distance 414 should preferably be sized to account for both flow paths 402 and 404. The distance 412 may represent the gap between the movable center body 210 and the valve seat 240, when the movable center body 210 is in its fully open position. In contrast, the distance 410 may represent the separation between the movable center body 210 and the movable intermediary body 220 when the valve 200 is in its fully opened configuration. The distance 414 can be measured perpendicular to the first axis 213.

The present inventors have recognized that, in an implementation such as that depicted in FIG. 4, the overall conductance of valve 200 can be increased by adjusting dimensions of various components of the multi-stage poppet valve 200. In particular, the overall conductance of valve 200 can be increased by increasing the cross-sectional areas of flow paths 402 and 404, while respecting space constraints within the semiconductor processing chamber (e.g., avoiding excessively large travel distances such as distances 406 and 412, which could cause one or more of the movable bodies to impinge on overhead components such as substrate support arm 122).

In some embodiments, it may be desirable for the distance 408 to be approximately equal to the distance 406. As examples, the distance 406 may be between 50% and 150% of the distance 408, between 75% and 125% of the distance 408, between 90% and 110% of the distance 408, at least 75% of the distance 408, at least 90% of the distance 408, no more than 125% of the distance 408, or no more than 110% of the distance 408. Such arrangements improve the potential conductance of flow path 402 by generally balancing the two chokepoints along the flow path 402 (the first between the movable body and the walls 106, the second between the movable body and the valve seat). All examples of distances, including distances 406 and 408, provided herein are intended to refer to average distances, thus allowing for variations around the perimeter of the movable intermediary body 220, in the semiconductor processing chamber 102, and/or in other relevant structures.

In some embodiments, it may be desirable for the distance 412 to be approximately equal to the distance 414. As examples, the distance 412 may be between 50% and 150% of the distance 414, between 75% and 125% of the distance 414, between 90% and 110% of the distance 414, at least 75% of the distance 414, at least 90% of the distance 414, no more than 125% of the distance 414, or no more than 110% of the distance 414. Such arrangements improve the potential conductance of flow path 404 by generally balancing the two chokepoints along the flow path 404 (the first between the movable center body and the walls 106, the second between the movable center body and the movable intermediary body). It is noted that while the first chokepoint in flow path 404 (between the movable center body 210 and the walls 106 of the semiconductor processing chamber 102) is significantly larger in cross-sectional area than the second chokepoint, the first chokepoint is also a chokepoint for the other flow path 402 and thus its cross-sectional area is shared between both flow paths. Thus, even with its significantly larger cross-sectional area, the first chokepoint in flow path 404 remains relatively balanced with the second chokepoint. All examples of distances, including distances 412 and 414, provided herein are intended to refer to average distances, thus allowing for variations around the perimeter of the movable center body 210, in the semiconductor processing chamber 102, and/or in other relevant structures.

In various embodiments, the gap 408 represents an average gap between adjacent portions of the movable intermediary body 220 and the walls 106 of the semiconductor processing chamber 102 and the gap 414 represents an average gap between adjacent portions of the movable center body 210 and the walls 106 of the semiconductor processing chamber 102. An average gap between two structures may refer to an average of all the different gaps between the structures at all radial orientations. As an example, consider a circle within a square, with the circle being as large as possible while remaining entirely within the square. In such an example, the gap between the circle and the square varies between zero (where the circle is touching the square) and some non-zero maximum (measured along a line that passes through two opposite corners of the square). The average gap would be found by averaging together all the different gaps at every radial orientation (with equal weight to each radial orientation). In the simple example of a first circle centered within a second circle, the average gap is just the radius of the second circle less the radius of the first circle.

In some embodiments, it may be desirable for the radial thickness 416 of the movable intermediary body 220 to be approximately equal to the distance 412 minus distance 406. In other words, may be desirable for the radial thickness 416 of the movable intermediary body 220 to be approximately equal to the distance 410. As examples, the radial thickness 416 of the movable intermediary body 220 may be between 50% and of the distance 412 minus distance 406, between 75% and 125% of the distance 412 minus distance 406, between 90% and 110% of the distance 412 minus distance 406, at least 75% of the distance 412 minus distance 406, at least 90% of the distance 412 minus distance 406, no more than 125% of the distance 412 minus distance 406, or no more than 110% of the distance 412 minus distance 406. Such arrangements improve the conductance of the multi-stage poppet valve 200.

In some embodiments, the movable center body 210 and/or the movable intermediary body 220 may be formed of conductive materials and may be electrically coupled (e.g., shorted) to ground. Grounding the movable center body 210 and/or the movable intermediary body 220 may help to contain plasma within the semiconductor processing chamber 102.

As shown in FIG. 4, the valve seat 240 has a gas-impermeable region 241 with a radial width 418 and has a gas-permeable region 242, which may also be referred to as a valve throat. In some embodiments, it may be desirable for the radial width 418 of the valve seat 240 to be approximately equal to the distances 406 and 408. As examples, the radial width 418 of the valve seat 240 may be between 50% and 150% of the distance 406, between 75% and 125% of the distance 406, between 90% and 110% of the distance 406, at least 75% of the distance 406, at least 90% of the distance 406, no more than 125% of the distance 406, or no more than 110% of the distance 406. As additional examples, the radial width 418 of the valve seat 240 may be between 50% and 150% of the distance 408, between 75% and 125% of the distance 408, between 90% and 110% of the distance 408, at least 75% of the distance 408, at least 90% of the distance 408, no more than 125% of the distance 408, or no more than 110% of the distance 408. Such arrangements improve the conductance of the multi-stage poppet valve 200. All examples of measurements, including radial width 418, provided herein are intended to refer to average distances, unless otherwise stated.

In some embodiments, the distance 406 traveled by the movable intermediary body 220 relative to the valve seat 240, as well as the distance 410 traveled by the movable center body 210 relative to the movable intermediary body 220, may be approximately half of the average lateral cross-sectional dimension of an interior volume of the semiconductor processing chamber 102. In the case of a cylindrical semiconductor processing chamber 102, the average lateral cross-sectional dimension of the interior volume is represented by the diameter of the chamber. For chambers of other shapes, including non-uniform shapes, the average lateral cross-sectional dimension of the interior volume can be found by averaging the lateral (horizontal) dimensions of the interior volume in a plurality of cross-sectional planes coincident with a common vertical axis and at a plurality of different angles relative to one of the cross-sectional planes. As a specific example, the distance 406 may be between 35% and 65% of the average lateral cross-sectional dimension of an interior volume of the semiconductor processing chamber 102. Similarly, the distance 408 may be between 35% and 65% of the average lateral cross-sectional dimension of an interior volume of the semiconductor processing chamber 102.

In some embodiments, the distance 406 traveled by the movable intermediary body 220 relative to the valve seat 240 may be approximately equal to the distance 410 traveled by the movable center body 210 relative to the movable intermediary body 220. As a particular example, the distance 406 may be between 75% and 125% of the distance 410.

In some embodiments, it may be desirable to balance various cross-sectional areas in the flow paths 402 and 404. In particular and when the valve 200 is in its fully open configuration (as shown in FIG. 4), there is a first cross-sectional area between the movable intermediary body 220 and the walls 106 of the semiconductor processing chamber 102, a second cross-sectional area between the movable intermediary body 220 and the valve seat 240, a third cross-sectional area between the movable center body 210 and the walls 106 of the semiconductor processing chamber 102, and a fourth cross-sectional area between the movable center body 210 and the gas-permeable region 223 of the movable intermediary body 220. In various embodiments, the first cross-sectional area may be approximately equal to the second cross-sectional area. As an example, the first cross-sectional area may be between 75% and 125% of the second cross-sectional area. In various embodiments, the third cross-sectional area may be approximately equal to the sum of the second and fourth cross-sectional areas. As an example, the third cross-sectional area may be between 75% and 125% of the sum of the second and fourth cross-sectional areas. In some embodiments, the cross-sectional area of the gas-permeable regions 223 of the movable intermediary body 220 may be approximately equal to (e.g., between 75% and 125% of) the fourth cross-sectional area. In some embodiments, the cross-section area of the gas-permeable region 242 of the valve seat 240 may be approximately equal to (e.g., between 75% and 125% of) the third cross-sectional area.

If desired, the valve 200 of the FIG. 4 embodiment may be operated in configurations between its fully closed and fully opened configurations. Starting from a fully closed configuration, the movable center body 210 may be translated independently until it is spaced apart from the movable intermediary body 220 by distance 410. Then, the movable center body 210 and the movable intermediary body 220 may be translated in unison until the valve 200 is in its fully opened configurations. Operating the valve 200 in such in-between configurations may provide for controlled modulation of the conductance of the valve 200, which can be helpful in regulating vacuum within a semiconductor processing chamber.

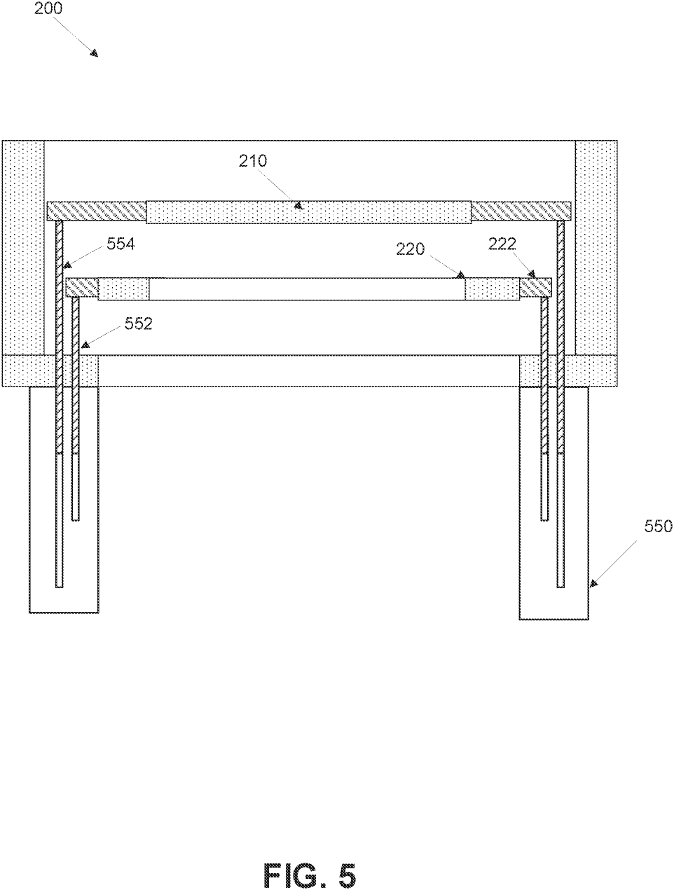

In various embodiments, the movable bodies of the multi-stage poppet valve 200 may move in different manners. As examples, the movement of a first one the movable bodies may be independent, semi-independent, or dependent on the movement of a second one of the movable bodies. The FIG. 4 embodiment discussed above is an example of a semi-independent configuration, as the movable center body 210 can be moved independently between the fully opened configuration and a partially opened configuration, while the movable center body 210 and movable intermediary body 220 move in unison between the partially opened configuration and a fully opened configuration. As another example of a semi-independent configuration, the movable center body 210 and the movable intermediary body 220 may move in unison between the fully closed configuration and a partially opened configuration, while the movable center body 210 moves independently between the partially opened configuration and the fully opened configuration. As an example of a dependent configuration, the two movable bodies can be configured to move simultaneously, but at different rates. As a specific example of a dependent configuration, the movable center body 210 could be configured to move simultaneously with, but at twice the speed of, the movable intermediary body 220, such that the movable bodies arrive at their fully opened positions and fully closed positions substantially simultaneously. An example of an independent configuration is provided by FIG. 5, which is discussed in more detail below.

### A Multi-Stage Poppet Valve with Independent Stage Actuation

FIG. 5 illustrates a multi-stage poppet valve 200 modified to have independent stage actuation. As discussed above at least in connection with FIG. 2, the multistage poppet valve 200 may include actuators 230 with stepped shafts 231. When the valve is transitioning from a fully closed state to a fully opened state, the steps in the shafts 231 enable movement of the shafts 231 to at first result in translation of only the movable center body 210 and then, after the movable center body 210 is in its spaced-apart relationship with the movable intermediary body 220, further movement of the shafts 231 results in translation of both the movable center body 210 and the moveable intermediary body 220 in unison. In contrast with such embodiments, the embodiment of FIG. 5 utilizes one or more actuators 550, each of which drives independent shafts 552 and 554. Shafts 552 are mechanically coupled to the movable intermediary body 220, while shafts 554 are mechanically coupled to the movable center body 210.

The arrangement of FIG. 5 may enable finer control of the conductance of the multi-stage poppet valve 200. In particular, the arrangement of FIG. 5 enables the moveable intermediary body 220 to be partially or fully translated into its fully opened position, while the movable center body 210 can be independently translated into any position between, and including, its fully opened position and a position proximate the movable intermediary body 220 (which may be in its fully closed position, its fully open position, or a partially open position therebetween). By enabling a wider diversity of states of the multi-stage poppet valve 200, the actuators 550 with independent shafts 552. and 554 can enable finer control of conductance through the valve.

### A Multi-Stage Poppet Valve with Nested Movable Bodies

In the above-discussed examples, the movable bodies, when in the minimum flow conductance state, may be stacked atop each other, with the gas-impermeable region of each body overlapping the boundary between the gas-permeable region and the gas-impermeable region of the adjacent body or bodies (or valve seat). This arrangement may provide for good sealing (e.g., a good face seal) between the bodies and the valve seat since surface-to-surface contact (or surface-to-seal contact if seals are used) can be easily achieved with a minimum of potential particulate generation, as there is no sliding contact between the bodies. However, in other implementations, the movable bodies and valve seat of the multi-stage poppet valve 200 may be configured to nest together when in a fully or partially closed configuration. Example arrangements of such implementations are illustrated in FIGS. 7A, 7B, and 7C.

As shown in FIG. 7A, the movable center body 210, movable intermediary body 220, and valve seat 240 may nest together when in a fully closed position. In some embodiments, the movable intermediary body 220 remains nested in the valve seat 240 while the valve 200 is in or between its fully closed position and its stage 1 fully open position (e.g., with the movable center body fully lifted off the valve seat while the movable intermediary body remains in its closed position). FIG. 7B illustrates the arrangement of a valve 200 including nesting movable bodies of the type shown in FIG. 7A, but with the valve 200 in its fully opened configuration. The nesting movable bodies may facilitate sealing (e.g., one or more piston seals) between the movable bodies and valve seat 240.

In the arrangements of FIGS. 7A and 7B, the nesting components of the valve 200 have vertically-oriented sides (e.g., sides parallel to the axis of travel of the movable bodies). If desired, seals, such as O-rings, may be provided in between the sides to provide a hermetic seal between the movable intermediary body 220 and the valve seat 240 and/or between the movable intermediary body 220 and the movable center body 210.

FIG. 7A also illustrates that actuators such as actuators 230 may include one or more seals 700. The seals 700 may provide a hermetic seal between an interior volume of the semiconductor processing chamber and the actuator 230, which may be disposed outside the interior volume of the semiconductor processing chamber. As depicted in FIGS. 7A and 7B, seals 700 are formed as sliding seals. In other embodiments, seals 700 may be formed from non-sliding seals such as static seals and/or bellows, which may be formed of metal. In various embodiments, internal components of actuators 230 may be outside a vacuum environment (e.g., at atmospheric pressure).

As an alternative to the nesting arrangement of FIGS. 7A and 7B, the nesting components of valve 200 may have sides with matching tapers (which may facilitate a tapered seal). In particular, the valve seat 240 may have a side that tapers outward (towards the walls of the semiconductor processing chamber) along the first axis (e.g., the direction of travel of the movable bodies of the valve 200), the movable intermediary body 220 may have an outer edge that tapers outwards along the first axis and an inner edge that tapers inwards along the first axis, and the movable center body 210 may have an outer edge that tapers outwards along the first axis. The tapering of the movable bodies 210 and 220 and the valve seat 240 may assist, as an example, with creating hermetic seals between the movable bodies 210 and 220 and the valve seat. If desired, seals, e.g., O-rings, may be provided to provide a hermetic seal between the movable intermediary body 220 and the valve seat 240 and/or between the movable intermediary body 220 and the movable center body 210, in the embodiment of FIG. 7C.

### A Multi-Stage Poppet Valve with the Intermediary Movable Body as a First Stage

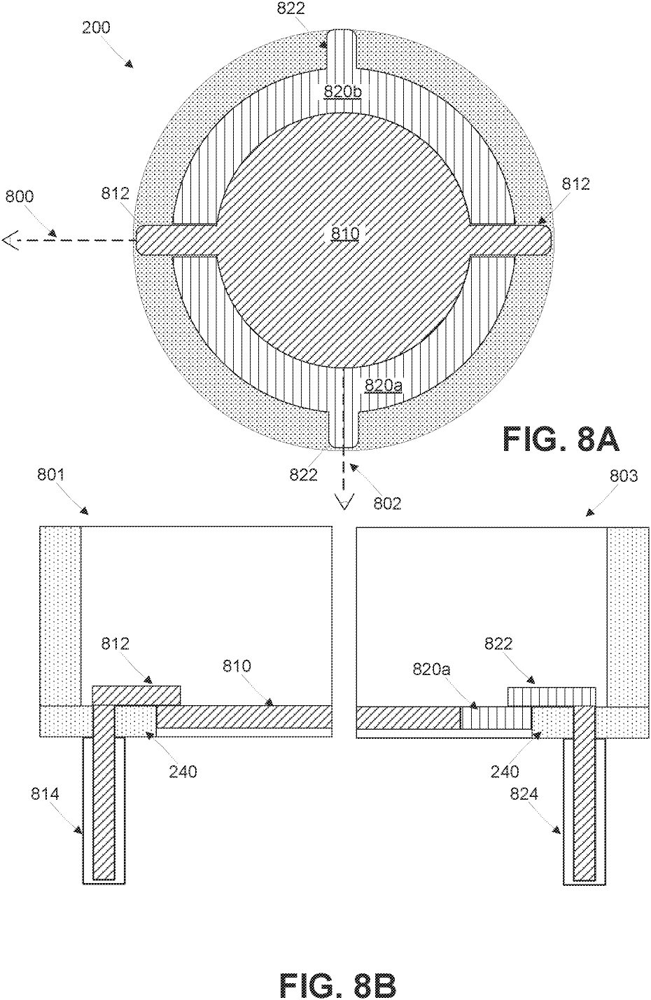

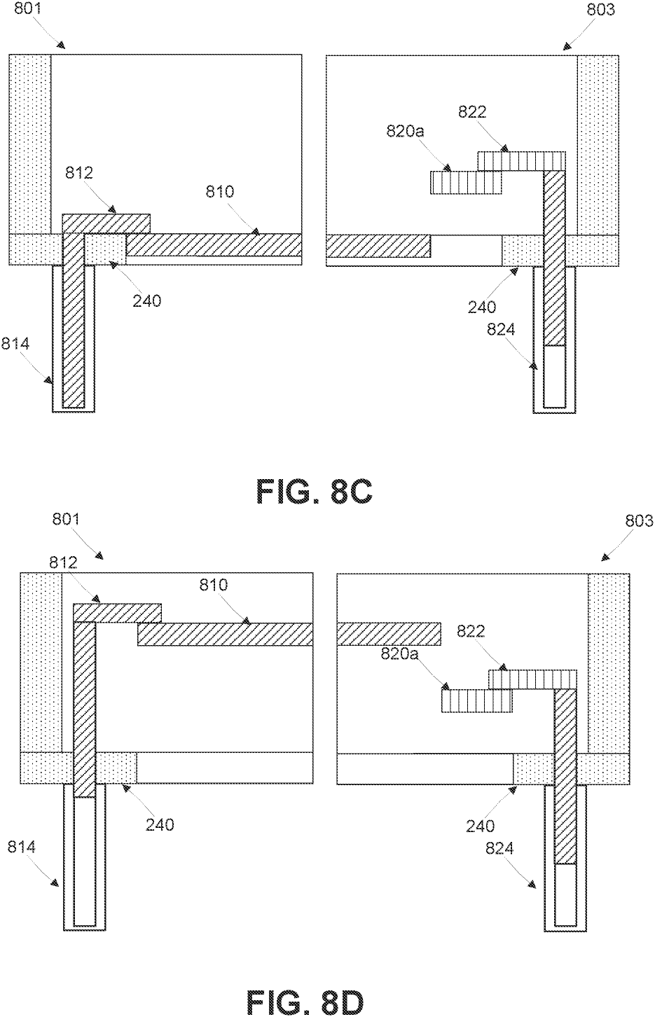

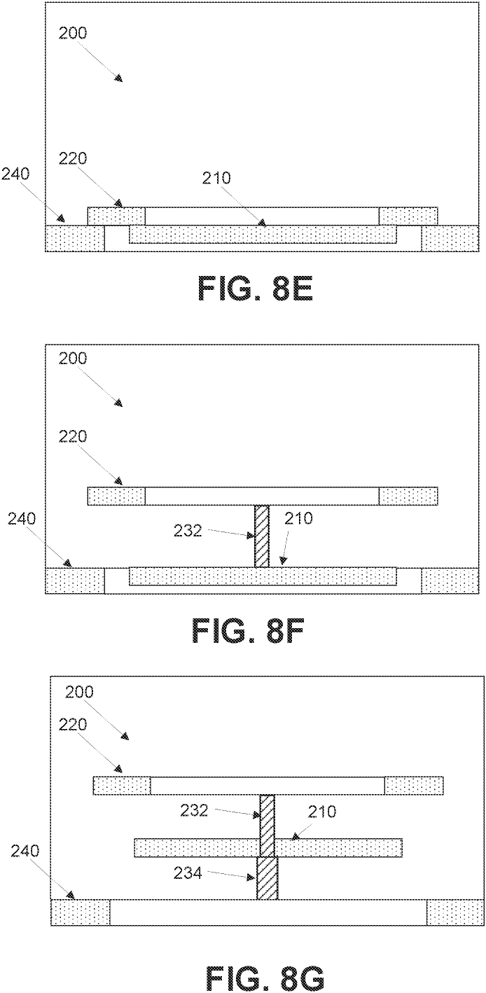

In contrast with previous embodiments in which an initial opening from a fully closed state involves moving the movable center body away from the valve seat, a multi-stage poppet valve such as valve 200 may be configured such that the movable intermediary body is the first movable body to move during an initial opening from a fully closed state. Arrangement of this type are illustrated in FIGS. 6D―6F and in FIGS. 8A―8D. Such arrangements may allow the valve 200 to reach a high-flow condition earlier since the intermediary body 220, when separated from the valve seat 240 and the center body 210 by a gap, may allow gas to flow by it both around the outside periphery of the intermediary body 220 and through the gas-permeable region of the intermediary body 220.

In some embodiments in which the movable intermediary body is the first movable body to move during an initial opening from a fully closed state, the moveable center body may need pass through the plane of the movable intermediary body. In the embodiments of FIGS. 8A-8D, this is accomplished by splitting the movable intermediary body into two portions 820a and 820b, each of which is coupled to an actuator 824 through a respective wing 822, as shown in FIG. 8A. Then, the movable center body 810 can be configured with wings 812 that can pass through gaps between the two movable intermediary body portions 820a and 820b. In some configurations, the valve 200 provides a hermetic seal in its fully closed configuration, with one or more hermetic seals between respective surfaces of the two movable intermediary body portions 820a and 820b, the wings 812 of the movable center body 810, the movable center body, and the valve seat 240.

If desired, independent actuators may be provided for translating the movable center body 810 and the two movable intermediary body portions 820a and 820b. As an example, one or more actuators 814 may be coupled to wings 812 of the moveable center body 810, while one or more actuators 824 may be coupled to each of the two movable intermediary body portions 820a and 820b.

While FIG. 8A illustrates the movable intermediary body being split into roughly equal halves, this is merely one arrangement. If desired, the moveable intermediary body could be split unequally and/or into more than two portions. The two or more moveable intermediary body portions 820a and 820b may be translated together in unison or, if desired, independently. Independent translation of the two or more moveable intermediary body portions 820a and 820b may enable finer control of conductance and/or control of the spatial distribution of the conductance, which may help with spatial tuning of plasma within the semiconductor processing chamber. A similar effect may be realized with a single-piece intermediary body having a C-shape, where the center body has a single wing that passes through the gap in the C-shape and is lifted by a single actuator.

FIGS. 8B, 8C, and 8D illustrates various configurations of a valve 200 of the type set forth in the embodiment of FIG. 8A (e.g., a valve where the movable intermediary body is the first movable body to move during an initial opening from a fully closed state). In FIG. 8A, the valve 200 of FIG. 8A is in its fully closed state. In FIG. 8C, the valve 200 of FIG. 8A is in a partially opened state (e.g., with the moveable intermediary body portions 820a and 820b in their fully opened positions). In FIG. 8D, the valve 200 of FIG. 8A is in a fully opened state. FIGS. 8B-8D illustrate cross-sections 801, which are taken along dashed line 800 of FIG. 8A, and cross-sections 802, which are taken along dashed line 802.

In some embodiments in which the movable intermediary body 220 is the first movable body to move during an initial opening from a fully closed state, the movable intermediary body 220 is stacked on top of the movable center body 210 in both the fully open and fully closed configurations. An arrangement of this type is illustrated in FIGS. 8E-8G. In FIG. 8E, the valve 200 is in its fully closed state. In FIG. 8F, the valve 200 is in a partially opened state with the moveable intermediary body 220 in a partially opened position. In FIG. 8G, the valve 200 is in a fully opened state. One benefit of the arrangement illustrated in FIGS. 8E-8G is that, if desired, actuators may be shared by the movable bodies. As examples, the actuators may include stepped shafts and/or the movable bodies may include hangers that enable multiple movable bodies to be translated by one or more shared actuators, as discussed in further detail in other sections of this disclosure.

### A Multi-Stage Poppet Valve with Hangers

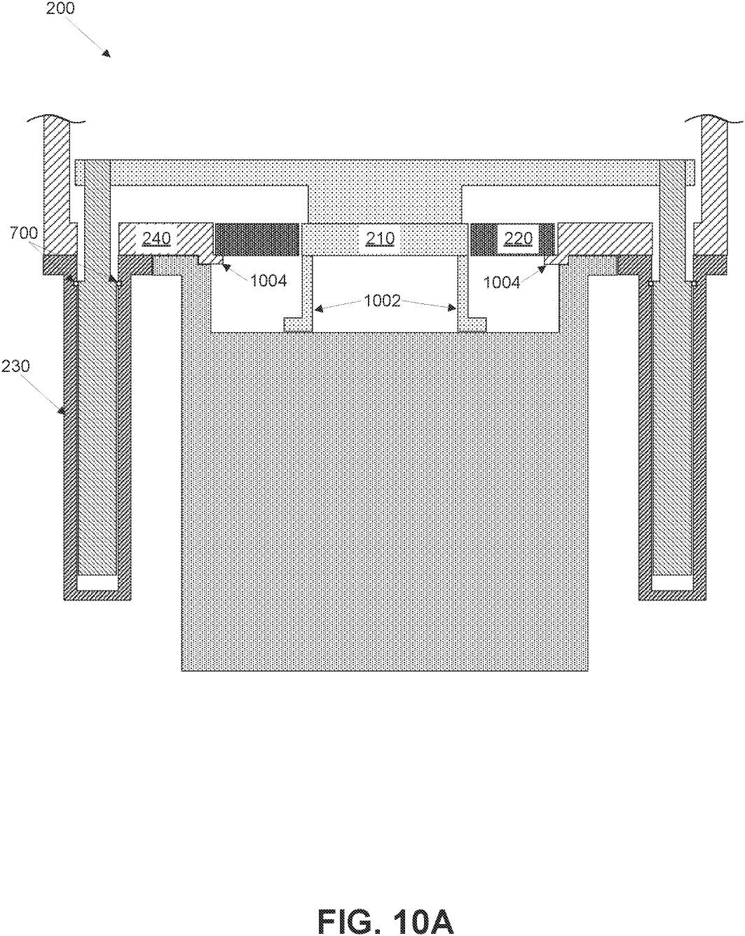

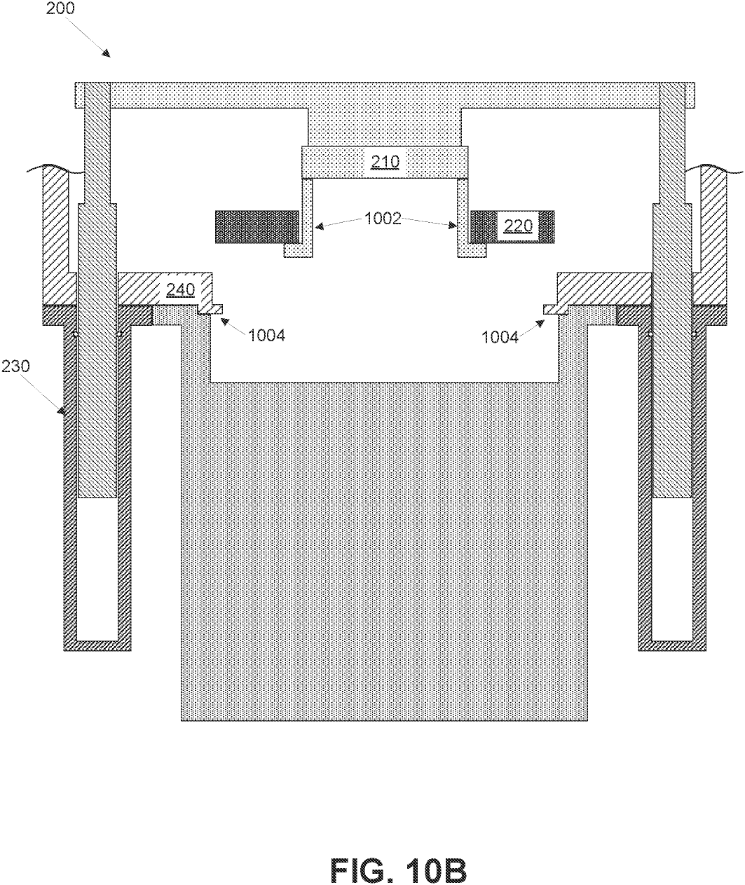

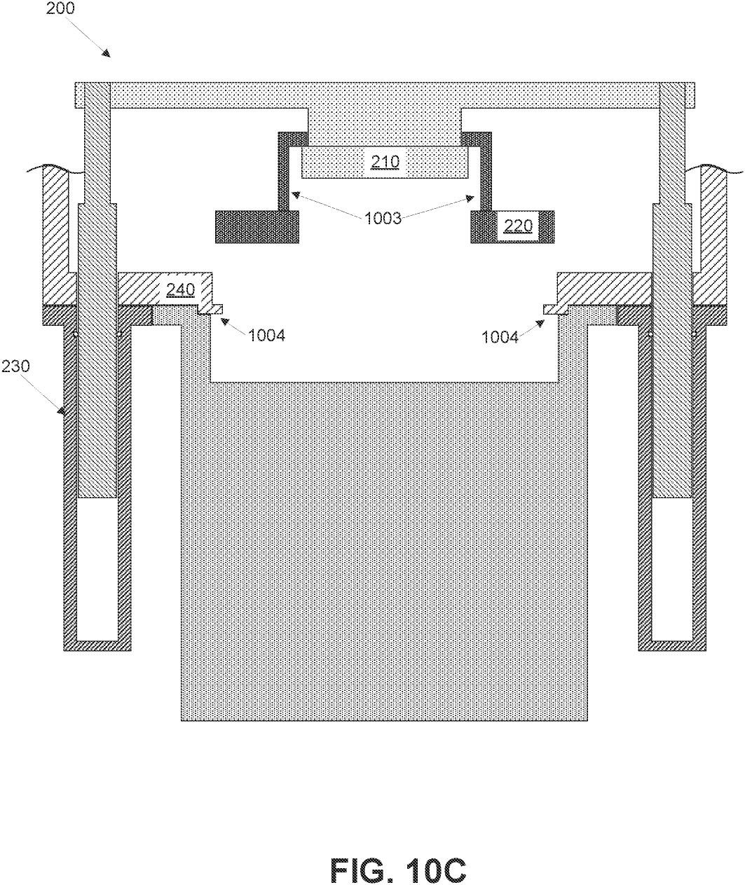

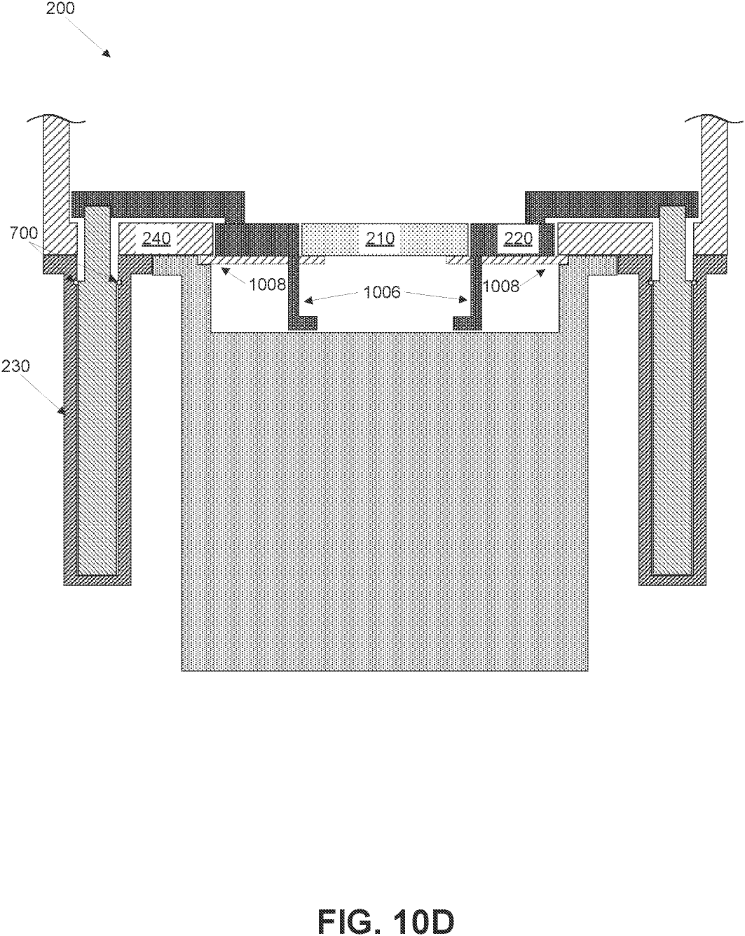

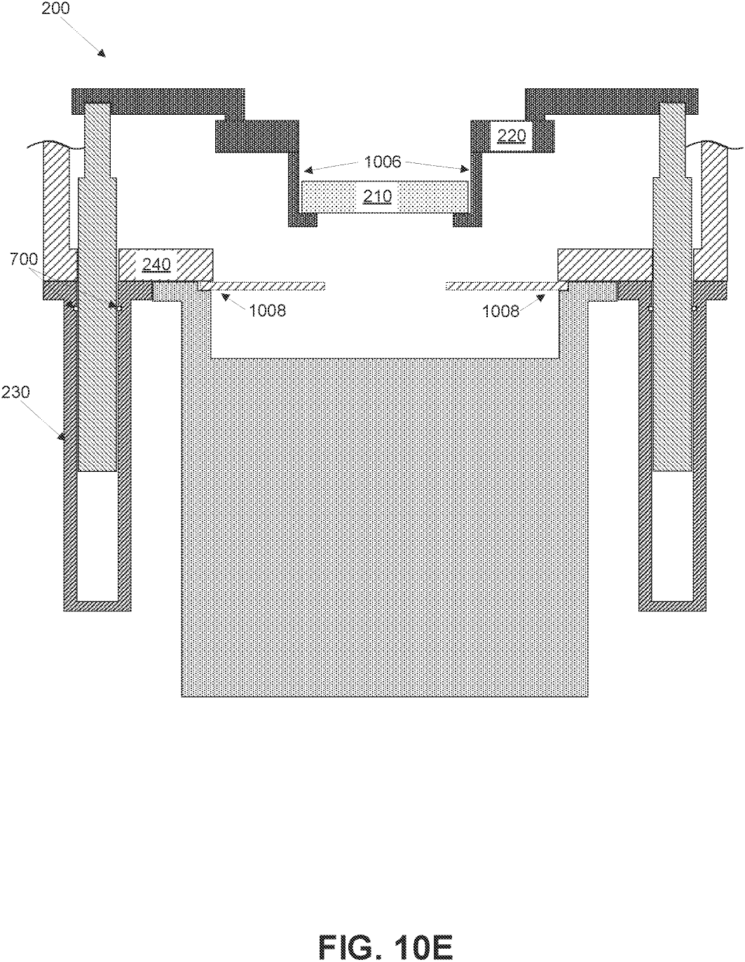

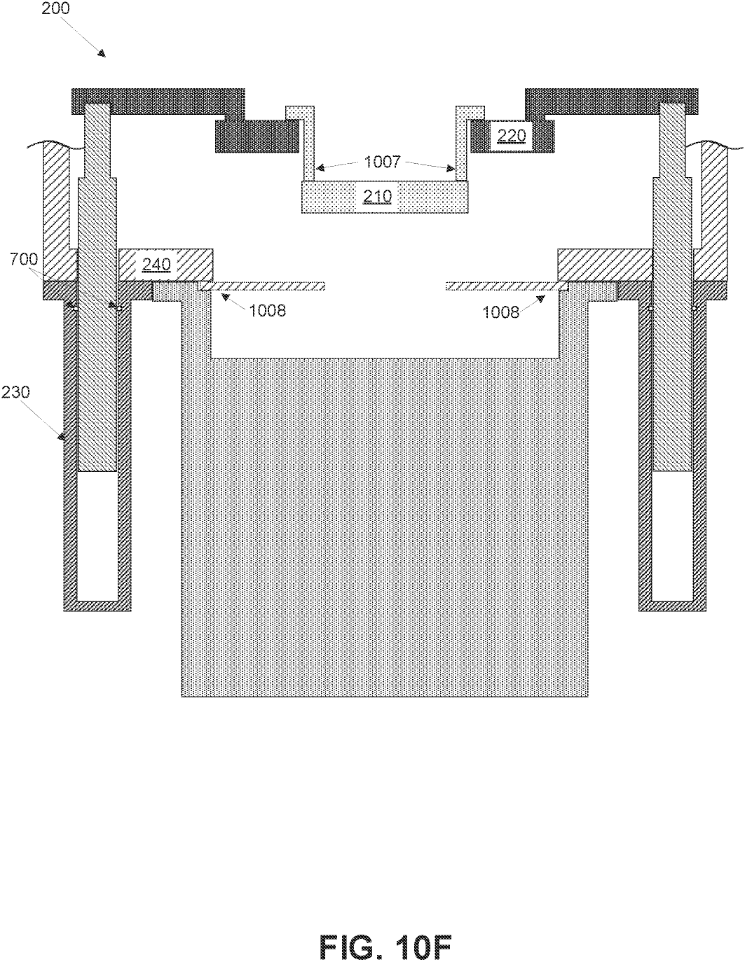

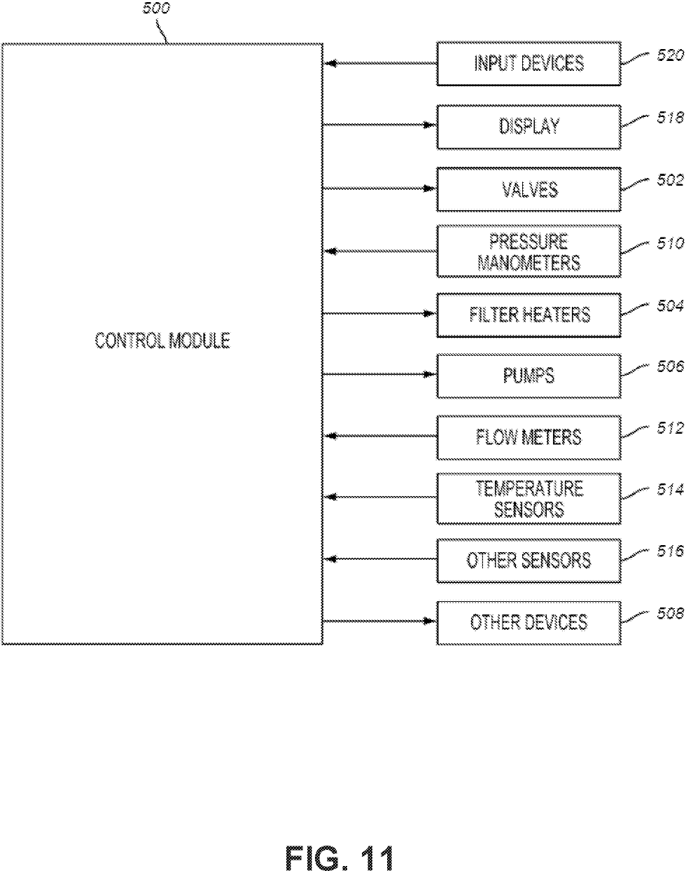

In contrast with previous embodiments in which the movable center body and the movable intermediary body are each coupled to actuator, a multi-stage poppet valve such as valve 200 may be configured where only a first movable body is coupled to an actuator or actuators and where one or more hangers, brackets, or other such structures couple the first movable body to the second movable body. Arrangements of this type are illustrated in FIGS. 10A―10F.

As shown in FIGS. 10A and 10B, the movable center body 210 may include hangers 1002 that extend down and lift the movable intermediary body 220 when the movable center body 210 is sufficiently lifted away from the valve seat 240. Additionally, the valve seat 240, or other suitable structure, may include extensions 1004 that support the movable intermediary body 220 when it is not being lifted by the hangers 1002. As an alternative, hangers 1003 could be attached to and extend upward from the movable intermediary body 220, as shown in FIG. 10C. In such an alternative, the hangers 1003 catch on the movable center body 210 and lift the movable intermediary body 220, when the movable center body 210 is sufficiently lifted above the valve seat 240.

As shown in FIGS. 10D and 10E, the movable intermediary body 220 may include hangers 1006 that extend down and lift the movable center body 210 when the movable intermediary body 220 is sufficiently lifted away from the valve seat 240. Thus, FIGS. 10D and 10E illustrate an arrangement in which the movable intermediary body 220 is the first body to move away from the valve seat, when opening from a fully closed configuration. To prevent the movable center body 210 from falling through, the valve seat, or other suitable structure, may include extensions 1008 that support the movable center body 210 when it is not being lifted by the hangers 1006. FIGS. 10D and 10E illustrate the extensions 1008 with dashed outlines to indicate that the extensions 1008 may be positioned radially offset from hangers 1006, to prevent collisions. As an alternative, hangers 1007 could be attached to and extend upward from the movable center body 210, as shown in FIG. 1 0F. In such an alternative, the hangers catch on the movable intermediary body 220 and lift the movable center body 210, when the movable intermediary body 220 is sufficiently lifted above the valve seat 240. Structures such as hangers 1004, hangers 1006, hangers 1007, and extensions 1008 may be disposed at multiple radial positions around the circumference of the multi-stage poppet valve 200. Such structures may be disposed evenly or non-evenly around the circumference of the multi-stage poppet valve 200. In general, it may be desirable to provide such structures in a sufficient number and with sufficient spacing between the structures to provide stable support for the supported structure(s).

### Additional High-Conductance Valves

In some embodiments, a fabrication tool 100 may include a high-conductance valve as valve 143 of FIG. 1 other than a multi-stage poppet valve 200. Examples of such high-conductance valves are illustrated in FIGS. 9A-9C.

As shown in FIG. 9A, a butterfly vent may serve as a high-conductance valve 143 in FIG. 1. The butterfly vent may include one or more first bodies 902 with gas-permeable regions and gas-impermeable regions and one or more second bodies 904 with gas-permeable regions and gas-impermeable regions. In some embodiments, the first bodies 902 may be movable bodies and the second bodies 904 may be fixed bodies. The gas-permeable regions of the one or more second bodies 904 may also be referred to, in aggregate, as a valve throat. Transitioning the butterfly vent between its fully opened and fully closed position (and any intermediary position) may involve rotating the first bodies 902 about a central axis. As shown in image 906, the gas-impermeable regions of the first bodies 902 may block off gas-permeable regions of the second bodies 904 when the butterfly vent is in a fully closed position. When the butterfly vent is in a partially opened position, as shown in image 908, the gas-impermeable regions of the first bodies 902 may be partially blocking the gas-permeable regions between the second bodies 904 and may partially overlap (e.g., be recessed below, above, or within) the gas-impermeable regions of the second bodies 904 when viewed along the central axis. When the butterfly vent is in a fully opened position, as shown in image 910, the gas-impermeable regions of the first bodies 902 may be substantially or entirely aligned with the gas-impermeable regions of the second bodies 904, leaving the gas-permeable regions of both the first bodies 902 and the second bodies 902 aligned, thus providing a maximum conductance configuration. If desired, the second bodies 904 may also be configured to rotate about the same axis as the first bodies 902. In at least some embodiments, the first and second bodies 902 and 904 are configured to be transitionable between at least first and second configurations relative to each other through rotation of one or both the first and second bodies about a rotation axis. In the first configuration, gas-permeable regions of the first body 902 are in a state of maximum overlap with gas-permeable regions of the second body 904 when viewed along the rotation axis (thus the valve is in a maximum conductance state). In the second configuration, the gas-permeable regions of the first body 902 are in a state of maximum overlap with gas-impermeable regions of the second body 904 and the gas-permeable regions of the second body 904 are in a state of maximum overlap with gas-impermeable regions of the first body 902 (thus the valve is in a minimum conductance state).

If desired, a butterfly vent may include more than one layer of movable bodies, to further improve the maximum potential conductance. A butterfly vent having a single layer of movable bodies, as shown in FIG. 9A, is only about 50% gas-permeable when fully opened. A butterfly vent having two layers of movable bodies, where the first layer and second layers both align with one or more fixed bodies can be about 67% gas-permeable when fully opened. A butterfly vent having three layers of movable bodies can be about 75% gas-permeable when fully opened. In general, the maximum conductance of such butterfly valves is approximately equal to the number of movable layers divided by the number of movable layers plus one (where that one corresponds to the fixed body those movable layers align with in the fully open configuration).

As shown in FIG. 9B, a butterfly valve may serve as a high-conductance valve 143 in FIG. 1. The butterfly valve may include a first body 928 and a second body 926. In some embodiments, the first body 928 may be a movable body and the second body 926 may be a fixed body. In some other embodiments, the first and second bodies 928 and 926 may both be movable. In some embodiments, the second body 926 may be formed by the walls 106 of the semiconductor processing chamber 102. Transitioning the butterfly valve between its fully opened and fully closed position (and any intermediary position) may involve rotating the first body 928 about an axis. As shown in image 920, the first body 928 may block off gas-permeable regions between the second body 926 when the butterfly valve is in a fully closed position. The gas-permeable regions of the second body 926 may also be referred to as a valve throat. When the butterfly valve is in a partially opened position, as shown in image 922, the first body 928 may be only partially blocking the gas-permeable regions between the second body 926. When the butterfly valve is in a fully opened position, as shown in image 924, the first body 928 may be substantially aligned with the expected direction of gas flow and the gas-permeable regions between the second body 926 may be substantially open to gas flow, resulting in a maximum conductance condition for the butterfly valve.

As shown in FIG. 9C, an iris valve may serve as a high-conductance valve 143 in FIG. 1. The iris valve may include a plurality of first bodies 938, which may also be referred to herein as blades, and a second body 936. In some embodiments, the first bodies 938 may be movable bodies and the second body 936 may be a fixed body. In some embodiments, the second body 936 may be at least partly formed by the walls 106 of the semiconductor processing chamber 102. Transitioning the iris valve between its fully opened and fully closed position (and any intermediary position) may involve retracting the first bodies 928 into a recessed position under, above, or within the second body 936. As shown in image 930, the first bodies 938 may block off gas-permeable regions between the second body 936 when the iris valve is in a fully closed position. The gas-permeable regions of the second body 936 may also be referred to as a valve throat. In its fully closed position, the iris valve may provide a hermetic seal. When the iris valve is in a partially opened position, as shown in image 932, the first bodies 938 may be only partially blocking the gas-permeable regions between the second body 936 and may be partially recessed under, above, or within the second body 936. When the iris valve is in a fully opened position, as shown in image 934, the first bodies 938 may be substantially or entirely recessed under, above, or within the second body 936, such that the gas-permeable regions between the second body 936 may be substantially open to gas flow, resulting in a maximum conductance condition for the iris valve.

In some embodiments, the butterfly vent of FIG. 9A, the butterfly valve of FIG. 9B, and the iris valve of 9C may include valve throats with an average horizontal cross-sectional width that is between 85% and 100% of the average horizontal cross-sectional width of the adjacent portions of the semiconductor processing chamber. Similarly, the one or more first bodies (e.g., movable bodies) of the valves of FIGS. 9A-9C, may have an average horizontal cross-sectional width that is between 85% and 100% of the average horizontal cross-sectional width of the adjacent portions of the semiconductor processing chamber. A structure, such as a semiconductor processing chamber or valve, may a width that varies depending on radial orientation. The average horizontal cross-sectional width of such a structure may refer to an average of all the different widths of the structure at all radial orientations. As an example, a structure shaped like an ellipse has a minimum width (measured along the semi-minor axis and equal to two times magnitude of the semi-minor axis), has a maximum width, (measured along the semi-major axis and equal to two times magnitude of the semi-major axis), and a plurality of additional widths between the maximum and minimum widths (with the additional widths measured along radial orientations not parallel to either the semi-minor or semi-major axis). In the example of an ellipse, the average horizontal cross-sectional width is determined by averaging together the minimum width, the maximum width, and all of the additional widths. In the simple example of a circle, the average horizontal cross-sectional width is just the diameter of the circle. As specific examples, in the embodiment in which the semiconductor processing chamber is cylindrical and has a radius of R, the valve throat, and corresponding first bodies 902, of the butterfly vent of FIG. 9A may have a cross-sectional width that is between 85% and 100% of R; the valve throat, and corresponding first body 928, of the butterfly valve of FIG. 9B may have a cross-sectional width that is between 85% and 100% of R; and the valve throat, and corresponding first bodies 938 (at least in their fully closed positions), of the iris valve of FIG. 9C may have a cross-sectional width that is between 85% and 100% of R.

### Control Module

FIG. 11 shows a control module 500 for controlling the systems described above. In one embodiment, the controller 124 of FIG. 1 may include some of the example components. For instance, the control module 500 may include a processor, memory and one or more interfaces. The control module 500 may be employed to control devices in the system based in part on sensed values. For example only, the control module 500 may control one or more of valves 502 (which may include high-conductance valves such as valve 200), filter heaters 504, pumps 506, and other devices 508 based on the sensed values and other control parameters. The control module 500 receives the sensed values from, for example only, pressure manometers 510, flow meters 512, temperature sensors 514, and/or other sensors 516. The control module 500 may also be employed to control process conditions during precursor delivery and deposition of the film and/or during etching processes. The control module 500 will typically include one or more memory devices and one or more processors.

The control module 500 may control activities of the precursor delivery system and deposition and/or etch apparatus. The control module 500 executes computer programs including sets of instructions for controlling process timing, delivery system temperature, pressure differentials across the filters, valve positions, mixture of gases, chamber pressure, chamber temperature, wafer temperature, RF power levels, wafer chuck or pedestal position, and other parameters of a particular process. The control module 500 may also monitor the pressure differential and automatically switch vapor precursor delivery from one or more paths to one or more other paths. Other computer programs stored on memory devices associated with the control module 500 may be employed in some embodiments.

Typically there will be a user interface associated with the control module 500. The user interface may include a display 518 (e.g., a display screen and/or graphical software displays of the apparatus and/or process conditions), and user input devices 520 such as pointing devices, keyboards, touch screens, microphones, etc.

Computer programs for controlling delivery of precursor, deposition and other processes in a process sequence can be written in any conventional computer readable programming language: for example, assembly language, C, C++, Pascal, Fortran or others. Compiled object code or script is executed by the processor to perform the tasks identified in the program.

The control module parameters relate to process conditions such as, for example, filter pressure differentials, process gas composition and flow rates, temperature, pressure, plasma conditions such as RF power levels and the low frequency RF frequency, cooling gas pressure, and chamber wall temperature.

The system software may be designed or configured in many different ways. For example, various chamber component subroutines or control objects may be written to control operation of the chamber components necessary to carry out the processes. Examples of programs or sections of programs for this purpose include substrate positioning code, process gas control code, pressure control code, heater control code, and plasma control code.

A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition and flow rates and optionally for flowing gas into the chamber prior to deposition in order to stabilize the pressure in the chamber. A filter monitoring program includes code comparing the measured differential(s) to predetermined value(s) and/or code for switching paths. A pressure control program may include code for controlling the pressure in the chamber by regulating, e.g., a throttle valve in the exhaust system of the chamber. A heater control program may include code for controlling the current to heating units for heating components in the precursor delivery system, the substrate and/or other portions of the system. Alternatively, the heater control program may control delivery of a heat transfer gas such as helium to the wafer chuck.

Examples of sensors that may be monitored during processing include, but are not limited to, mass flow control modules, pressure sensors such as the pressure manometers 510, and thermocouples located in delivery system, the pedestal or chuck (e.g. the temperature sensors 514). Appropriately programmed feedback and control algorithms may be used with data from these sensors to maintain desired process conditions. The foregoing describes implementation of embodiments of the invention in a single or multi-chamber semiconductor processing tool.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power and/or vacuum valve state (and thus conductance). It will be appreciated that, in some embodiments, other monitors may be used to monitor the plasma and other process characteristics. Such monitors may include, but are not limited to, infrared (IR) monitors, acoustic monitors, and pressure transducers.

Any suitable chamber may be used to implement the disclosed embodiments. Example deposition apparatuses include, but are not limited to, apparatus from the ALTUS® product family, the VECTOR® product family, and/or the SPEED® product family, each available from Lam Research Corp., of Fremont, California, or any of a variety of other commercially available processing systems. Two or more of the stations may perform the same functions. Similarly, two or more stations may perform different functions. Each station can be designed/configured to perform a particular function/method as desired.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller. The signals for controlling the process are output on the analog and digital output connections of the deposition apparatus.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The tool 100 of FIG. 1 may include a system controller 124. The system controller 124 (which may include one or more physical or logical controllers) controls some or all of the operations of the tool 100. The system controller 124 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the system controller 124 they may be provided over a network. In certain implementations, the system controller 124 executes system control software.

The system control software may include instructions for controlling the timing of application and/or magnitude of any one or more of the following chamber operational conditions: the mixture and/or composition of gases, chamber pressure, the state of valve 143, the operational status of pump 144, the operational status of pump 145, chamber temperature, wafer/wafer support temperature, the bias applied to the substrate (which in various implementations may be zero), the frequency and power applied to coils or other plasma generation components, substrate position, substrate movement speed, and other parameters of a particular process performed by the tool. The system control software may further control heating operations, purge operations, and cleaning operations through the valve 143 and the vacuum pump 144. System control software may be configured in any suitable way. For example, various process tool component subroutines or control objects may be written to control operations of the process tool components necessary to carry out various process tool processes. System control software may be coded in any suitable compute readable programming language.

In some embodiments, system control software includes input/output control (IOC) sequencing instructions for controlling the various parameters described above. For example, each phase of a semiconductor fabrication process may include one or more instructions for execution by the system controller 124. The instructions for setting process conditions for a phase may be included in a corresponding recipe phase, for example. In some implementations, the recipe phases may be sequentially arranged, such that steps in a doping process are executed in a certain order for that process phase. For example, a recipe may be configured to perform etch operations and include one or more cycles of an atomic-layer-deposition (ALD) process performed in between each of the etch operations. The recipe may be configured to perform purge operations and/or clean operations between etch operations and the one or more cycles of the ALD process.

Other computer software and/or programs may be employed in some embodiments, Examples of programs or sections of programs for this purpose include substrate positioning program, a process gas composition control program, a pressure control program, a heater control program, and an RF power supply control program.

In some cases, the system controller 124 controls gas concentration, substrate movement, and/or the power supplied to the coil 110 and/or substrate support 120. The system controller 124 may control the gas concentration by, for example, opening and closing relevant valves to produce one or more inlet gas stream that provide the necessary reactant(s) at the proper concentration(s). The system controller 124 may also control the gas concentration by, for example, regulating the state of valve 143 (between open, closed, and intermediary positions) and controlling pumps 144 and 145. The substrate movement may be controlled by, for example, directing a substrate positioning system to move as desired. The power supplied to the coil 110 and/or substrate support 120 may be controlled to provide particular RF power levels.

The system controller 124 may control these and other aspects based on sensor output (e.g., when power, potential, pressure, gas levels, etc. reach a certain threshold), the timing of an operation (e.g., opening valves at certain times in a process, purging, etc.), or based on received instructions from the user.

In some implementations, a system controller 124 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 124, depending on the processing requirements and/or the type of system, may be programmed to control any of the processes disclosed 104, including the delivery of etch gases and deposition precursors into the plasma chamber 132, temperature settings (e.g., heating and/or cooling), pressure settings, vacuum settings, valve setting, power settings, RF generator settings, RF matching circuit settings, frequency settings, flow rate settings, fluid delivery settings, positional and operation settings, substrate transfers into and out of a tool, and purging of gases and byproducts from the plasma chamber 104.

Broadly speaking, the system controller 124 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 124 in the form of various individual settings (or program files), defining operational parameters for carrying out a particular process on or for a semiconductor substrate or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a substrate.

The system controller 124, in some implementations, may be a part of or coupled to a computer that is integrated with, coupled to the system, otherwise networked to the system, or a combination thereof. For example, the system controller 124 may be in the “cloud” or all or a part of a fab host computer system, which can allow for remote access of the substrate processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 124 receives instructions in the form of data, which specify parameters for each of the processing steps to be performed during one or more operations. It should be understood that the parameters may be specific to the type of process to be performed and the type of tool that the system controller 124 is configured to interface with or control. Thus as described above, the system controller 124 may be distributed, such as by including one or more discrete controllers that are networked together and working towards a common purpose, such as the processes and controls described herein. An example of a distributed system controller 124 for such purposes would be one or more integrated circuits on a chamber in communication with one or more integrated circuits located remotely (such as at the platform level or as part of a remote computer) that combine to control a process on the chamber.

As noted above, depending on the process step or steps to be performed by the tool, the system controller 124 might communicate with one or more of other tool circuits or modules, other tool components, cluster tools, other tool interfaces, adjacent tools, neighboring tools, tools located throughout a factory, a main computer, another system controller 124, or tools used in material transport that bring containers of substrates to and from tool locations and/or load ports in a semiconductor manufacturing factory.

The plasma power supply 106 and the wafer bias voltage power supply 116 may be configured to operate at specific radio frequencies such as, for example, 13.56 MHz, 27 MHz, 2 MHz, 60 MHz, 100 kHz, 2.54 GHz, or combinations thereof. Plasma power supply 106 and wafer bias voltage power supply 116 may be appropriately sized to supply a range of powers in order to achieve desired process performance. In addition, the TCP coil 110 and/or the substrate support 120 may include two or more sub-coils or sub-electrodes, which may be powered by a single power supply or powered by multiple power supplies.

### Conclusion

For the purposes of this disclosure, the term “fluidically connected” is used with respect to volumes, plenums, openings, holes, etc., that may be connected with one another in order to form a fluidic connection, similar to how the term “electrically connected” is used with respect to components that are connected together to form an electric connection. The term “fluidically interposed,” if used, may be used to refer to a component, volume, plenum, or hole that is fluidically connected with at least two other components, volumes, plenums, or holes such that fluid flowing from one of those other components, volumes, plenums, or holes to the other or another of those components, volumes, plenums, or holes would first flow through the “fluidically interposed” component before reaching that other or another of those components, volumes, plenums, or holes. For example, if a pump is fluidically interposed between a reservoir and an outlet, fluid that flowed from the reservoir to the outlet would first flow through the pump before reaching the outlet.

It is to be understood that the phrases “for each <item> of the one or more <items>,” “each <item> of the one or more <items>,” or the like, if used herein, are inclusive of both a single-item group and multiple-item groups, i.e., the phrase “for ... each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

Terms such as “about,” “approximately,” “substantially,” “nominal,” or the like, when used in reference to quantities or similar quantifiable properties, are to be understood to be inclusive of values within ±10% of the values or relationship specified (as well as inclusive of the actual values or relationship specified), unless otherwise indicated.

The use, if any, of ordinal indicators, e.g., (a), (b), (c)... or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood. It is also to be understood that use of the ordinal indicator “first” herein, e.g., “a first item,” should not be read as suggesting, implicitly or inherently, that there is necessarily a “second” instance, e.g., “a second item.”

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments are described in conjunction with the specific embodiments, it will be understood that it is not intended to limit the disclosed embodiments.

In the present disclosure and claims, “and/or” is intended to indicate “at least one of.” As an example, any disclosure or claim here that describes a structure as having aspect A, aspect B, and/or aspect C is intended to indicate that the structure has at least one of aspect A, aspect B, and aspect C.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. An apparatus, comprising a multi-stage poppet valve, the multi-stage poppet valve comprising:
a valve seat including a gas-permeable region;
two or more movable bodies comprising (i) a movable center body including a gas-impermeable region and (ii) at least one movable intermediary body, each movable intermediary body including a gas-impermeable region and a gas-permeable region, the gas-impermeable region of each movable intermediary body surrounding the gas-permeable region of that movable intermediary body, wherein:
each of the movable bodies is translatable relative to the valve seat along a first axis and the movable bodies are transitionable between at least a first configuration and a second configuration,
the movable bodies, in the first configuration, are positioned proximate the valve seat to provide a first amount of flow restriction, and
the movable bodies, in the second configuration, are positioned at spaced-apart locations along the first axis and relative to each other and the valve seat to provide a second amount of flow restriction less than the first amount of flow restriction and such that a first gap is visible along the first axis, the first gap being between at least two of the movable bodies in a first set of the movable bodies and such that corresponding second gaps are visible along the first axis, the second gaps being between each of the movable bodies in the first set of the movable bodies and the valve seat.

2. The apparatus of claim 1, wherein the movable bodies are additionally transitionable between a continuum of additional configurations between the first and second configurations and wherein, as the movable bodies transition from the first configuration, through the continuum of additional configurations, and into the second configuration, the movable bodies provide a variable amount of flow restriction that ramps down from the first amount of flow restriction to the second amount of flow restriction.

3. The apparatus of claim 1 further comprising:
at least one actuator configured to translate the movable bodies, wherein:
each of the movable bodies includes a main body, and
each movable body of the movable bodies includes at least one wing that extends off the main body and mechanically couples to a respective portion of the actuator.

4. The apparatus of claim 1 further comprising:
at least one actuator configured to translate the movable bodies, wherein:
at least one of the movable bodies includes a main body,
at least one movable body of the movable bodies includes at least one wing that extends off the main body and mechanically couples to a portion of the actuator, and
at least one movable body of the movable bodies includes at least one bracket that extends off the main body and mechanically engages another one of the movable bodies for a partial fraction of the translation of the movable bodies between the first and second configurations.

5. The apparatus of claim 1 further comprising:
a semiconductor processing chamber having walls defining an interior volume;
a process gas delivery system configured to introduce one or more process gases into the interior volume of the semiconductor processing chamber; and
a vacuum foreline in fluidic communication with the interior volume of the semiconductor processing chamber, wherein the multi-stage poppet valve is fluidically interposed between the vacuum foreline and the process gas delivery system.

6. The apparatus of claim 5 further comprising:
at least one actuator configured to translate the movable bodies;
a substrate support; and
a substrate support arm configured to hold the substrate support within the semiconductor processing chamber, wherein:
the substrate support arm mechanically couples a wall of the semiconductor processing chamber to the substrate support,
each of the movable bodies includes a main body and at least one wing that extends off the main body,
the wing of each movable body mechanically couples that movable body to a portion of the actuator, and
the substrate support arm and at least one wing of each movable body are aligned along a second axis parallel to the first axis.

7. (canceled)

8. (canceled)

9. The apparatus of claim 1, wherein the multi-stage poppet valve further comprises:
a first actuator or set of actuators configured to translate the movable center body, at least partially independent of the movable intermediary body, along the first axis and between the first and second configurations; and
a second actuator or set of actuators configured to translate the movable intermediary body, at least partially independent of the movable center body, along the first axis and between the first and second configurations.

10. The apparatus of claim 1, wherein the movable bodies are further transitionable to a third configuration in which the movable center body is positioned at a spaced-apart location along the first axis relative to the valve seat and in which the movable intermediary body is positioned proximate the valve seat to provide a third amount of flow restriction that is between the first and second amounts of flow restriction and wherein the multi-stage poppet valve further comprises:
at least one actuator; and
at least one shaft that is translated along the first axis by operation of the at least one actuator, the shaft having (i) a first portion that engages with the movable center body and (ii) a second portion that engages with the movable intermediary body.

11. The apparatus of claim 1, wherein the movable bodies are further transitionable to a third configuration in which the movable center body is positioned at a spaced-apart location along the first axis relative to the valve seat and the movable intermediary body is positioned proximate the valve seat to provide a third amount of flow restriction that is between the first and second amounts of flow restriction and wherein the multi-stage poppet valve further comprises:
at least one actuator; and
at least one stepped shaft that couples the at least one actuator to both the movable center body and the movable intermediary body, wherein a first portion of the stepped shaft has a first diameter and a second portion of the stepped shaft has a second diameter larger than the first diameter, wherein the first portion of the stepped shaft is coupled to the movable center body and passes between portions of the movable intermediary body, and wherein the second portion of the stepped shaft is configured to press against the portions of the movable intermediary body in order to translate the movable intermediary body along the first axis.

12. The apparatus of claim 1, wherein the multi-stage poppet valve further comprises at least first and second seals, wherein the first seal contacts both the valve seat and the movable intermediary body at least when in the first configuration, and wherein the second seal contacts both the movable intermediary body and the movable center body at least when in the first configuration.

13. The apparatus of claim 1, wherein, in the first configuration, the movable intermediary body nests within the gas-permeable region of the valve seat and the movable center body nests within the gas-permeable region of the movable intermediary body such that the valve seat, movable intermediary body, and movable center body all overlap each other when viewed along an axis perpendicular to the first axis.

14. The apparatus of claim 1, wherein, in the first configuration, the movable bodies and the valve seat are disposed in a stacked arrangement.

15-18. (canceled)

19. The apparatus of claim 1, wherein the movable center body and the movable intermediary body are additionally movable into a third configuration, wherein, in the third configuration, the movable intermediary body is positioned in a spaced-apart relationship from the valve seat and the movable center body is positioned proximate the movable intermediary body, and wherein the movable center body is translatable along the first axis, independent of the movable intermediary body, for at least a portion of a transition between the second and third configurations.

20. The apparatus of claim 1, wherein the movable center body and the movable intermediary body are additionally movable into a third configuration, wherein, in the third configuration, the movable intermediary body is positioned proximate the valve seat and the movable center body is positioned in a spaced-apart relationship from the valve seat and intermediary body, wherein the movable center body is translatable along the first axis, independent of the movable intermediary body, for at least a portion of a transition between the first and third configurations, and wherein the movable center body and the movable intermediary bodies are translatable in unison along the first axis for at least a portion of the transition between the second and third configurations.

21. The apparatus of claim 1, wherein the movable center body has a disc shape, wherein the movable intermediary body has a ring shape, and wherein the gas-permeable region of the valve seat has a disc shape.

22. The apparatus of claim 1, wherein the first configuration provides a maximum flow restriction condition and the second configuration provides a minimum flow restriction condition, wherein the movable center body travels a distance of X along the first axis when moving from the first configuration to the second configuration, wherein the movable intermediary body travels a distance of Y along the first axis when moving from the first configuration to the second configuration, wherein the movable intermediary body has a ring shape with an average radial width of A, and wherein A is at most 125% of X minus Y.

23. The apparatus of claim 1, wherein the movable center body travels a distance of X when moving from the first configuration to the second configuration, wherein the valve seat has gas-impermeable region with an average radial width of A, and wherein A is at most 125% of X.

24. The apparatus of claim 1, wherein the first configuration is a maximum flow restriction condition and wherein the multi-stage poppet valve is still gas-permeable in the maximum flow restriction condition.

25. (canceled)

26. The apparatus of claim 1 further comprising:
a semiconductor processing chamber at least partly enclosing a volume having an average lateral cross-sectional dimension;
a process gas delivery system configured to introduce one or more process gases into the semiconductor processing chamber; and
a vacuum foreline in fluidic communication with the semiconductor processing chamber, wherein:
the multi-stage poppet valve is fluidically interposed between the process gas delivery system and the vacuum foreline,
the movable intermediary body is configured to translate a first distance between the first configuration, in which the movable intermediary body is proximate to the valve seat, and the second configuration, in which the movable intermediary body is positioned away from valve seat by the first distance,
the movable intermediary body has an average lateral cross-sectional dimension,
the movable center body is configured to translate, relative to the movable intermediary body, a second distance between the first configuration, in which the movable center body is proximate to the gas-permeable of the movable intermediary body, and the second configuration, in which the movable center body is positioned away from the valve seat by the second distance and away from the movable intermediary body by the second distance minus the first distance,
the movable center body has an average lateral cross-sectional dimension,
the first distance is between 35% and 65% of the average lateral cross-sectional dimension of the volume of the semiconductor processing chamber less the average lateral cross-sectional dimension of the movable intermediary body; and
the second distance is between 35% and 65% of average lateral cross-sectional dimension of the movable intermediary body less the average lateral cross-sectional dimension of the movable center body.

27-30. (canceled)

31. The apparatus of claim 1 further comprising:
a semiconductor processing chamber;
a process gas delivery system configured to introduce one or more process gases into the semiconductor processing chamber; and
a vacuum foreline in fluidic communication with the semiconductor processing chamber, wherein:
the first configuration comprises a maximum flow restriction condition,
the second configuration comprises a minimum flow restriction condition,
when the movable intermediary body is in the second configuration, there is a first minimum cross-sectional area between the movable intermediary body and the semiconductor processing chamber and there is a second minimum cross-sectional area between the movable intermediary body and the valve seat,
the first minimum cross-sectional area is between 75% and 125% of the second minimum cross-sectional area,
when the movable intermediary body is in the second configuration and the movable center body is in the second configuration, there is a third minimum cross-sectional area between the movable center body and the semiconductor processing chamber and there is a fourth minimum cross-sectional area between the movable center body and the gas-permeable region of the movable intermediary body; and
the third minimum cross-sectional area is between 75% and 125% of the sum of the second minimum cross-sectional area and the fourth minimum cross-sectional area.

32-35. (canceled)
